(19) United States
(12) Patent Application Publication
(10) Pub. No.: US 2013/0130407 A1
(43) Pub. Date: May 23, 2013

(54) SEMICONDUCTOR DEVICE AND METHOD FOR MANUFACTURING THE SAME

(71) Applicant: Fujitsu Semiconductor Limited, Yokohama-shi (JP)

(72) Inventor: Wensheng WANG, Yokohama-shi (JP)

(21) Appl. No.: 13/740,240

(22) Filed: Jan. 13, 2013

Related U.S. Application Data
(62) Division of application No. 12/912,277, filed on Oct. 26, 2010.

(30) Foreign Application Priority Data
Oct. 29, 2009 (JP) 2009-248712

(51) Int. Cl. H01L 43/12

(52) U.S. Cl. CPC H01L 43/12
USPC 438/3

(57) ABSTRACT

A semiconductor device includes a capacitor, the capacitor includes a lower electrode, which includes platinum, provided above a semiconductor substrate; a first ferroelectric film, which includes lead zirconate titanate added with La, provided on the lower electrode; a second ferroelectric film, which includes lead zirconate titanate added with La, Ca, and Sr, provided directly on the first ferroelectric film, the second ferroelectric film having a thickness smaller than that of the first ferroelectric film and includes amounts of Ca and Sr greater than amounts of Ca and Sr that may be present in the first ferroelectric film; and an upper electrode, which includes a conductive oxide, provided on the second ferroelectric film.

### CROSS-REFERENCE TO RELATED APPLICATIONS

This application is a divisional of application Ser. No. 12/912,277, filed Oct. 26, 2010, which claims the benefit of priority of the prior Japanese Patent Application No. 2009-248712, filed on Oct. 29, 2009, the entire contents of which are incorporated herein by reference.

### FIELD

The present invention relates to a semiconductor device and a method for manufacturing the same.

### BACKGROUND

In recent years, the use of a ferroelectric film as a dielectric film of a capacitor has drawn attention.

A ferroelectric random access memory (FeRAM) using a ferroelectric capacitor as described above is a nonvolatile memory which is able to perform high speed operation, has a low power consumption, and has excellent durability in writing and reading. Hence, semiconductor devices each including a capacitor using a ferroelectric film have been expected to be more widely used in various fields.

In addition, in the fields of DRAMs and the like, in order to increase the degree of integration, a technique has also been proposed in which a ferroelectric film is used as a dielectric film of a capacitor.

However, in the capacitor using a ferroelectric film, sufficiently excellent properties have not always been obtained.

### SUMMARY

According to one aspect of the invention, a semiconductor device includes a capacitor, the capacitor includes a lower electrode, which includes platinum, provided above a semiconductor substrate; a first ferroelectric film, which includes lead zirconate titanate with La, provided on the lower electrode; a second ferroelectric film, which includes lead zirconate titanate with La, Ca, and Sr, provided directly on the first ferroelectric film, the second ferroelectric film having a thickness smaller than that of the first ferroelectric film and includes amounts of Ca and Sr greater than amounts of Ca and Sr that may be present in the first ferroelectric film; and an upper electrode, which includes a conductive oxide, provided on the second ferroelectric film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view of a semiconductor device according to a first embodiment;

FIGS. 2A to 2U are cross-sectional views illustrating a method for manufacturing the semiconductor device according to the first embodiment;

FIG. 3 is a graph (Part 1) of measurement results of inversion charge amounts of capacitors;

FIG. 4 is a graph (Part 2) of measurement results of the inversion charge amounts of the capacitors;

FIG. 5 is a graph (Part 3) of measurement results of the inversion charge amounts of the capacitors;

FIG. 6 is a graph of measurement results of leak currents of the capacitors;

FIG. 7 is a graph of measurement results of fatigue characteristics of the capacitors;

FIG. 8 is a graph illustrating the relationship between an applied voltage and the inversion charge amount of the capacitors;

FIG. 9 is a graph illustrating leak current characteristics of the capacitors;

FIG. 10 is a cross-sectional view illustrating a semiconductor device according to a second embodiment; and

FIGS. 11A to 11W are cross-sectional views illustrating a method for manufacturing the semiconductor device according to the second embodiment.

### DETAILED DESCRIPTION OF THE EMBODIMENTS

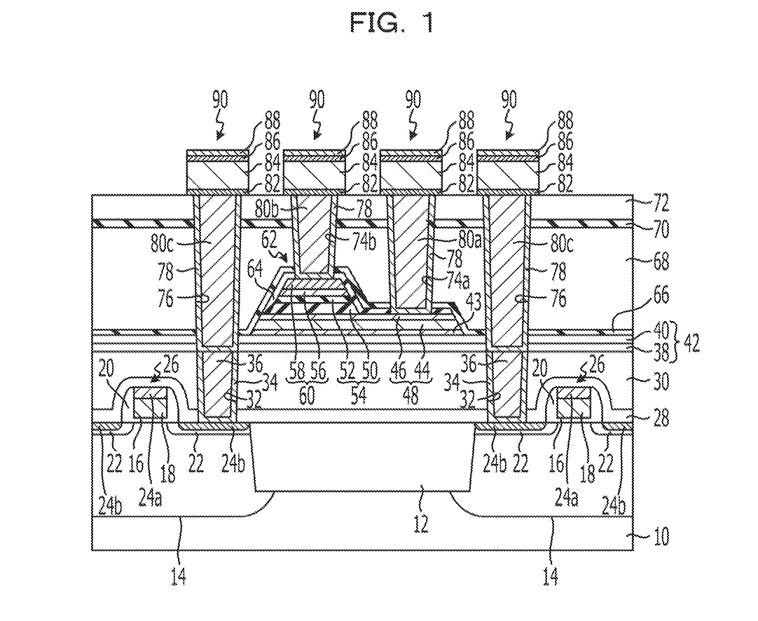

A semiconductor device according to a first embodiment and a manufacturing method thereof will be described with reference to FIGS. 1 to 9.

First, the semiconductor device according to this embodiment will be described with reference to FIG. 1. FIG. 1 is a cross-sectional view of the semiconductor device according to this embodiment.

The semiconductor device according to this embodiment is a device having a planar memory cell structure.

As illustrated in FIG. 1, in a semiconductor substrate 10, an element isolation region 12 defining an element region is formed. As the semiconductor substrate 10, for example, an N-type or a P-type silicon substrate is used. In the semiconductor substrate 10 in which the element isolation region 12 is formed, for example, a P-type well 14 is formed.

A gate electrode (word line) 18 is formed on the semiconductor substrate 10 in which the well 14 is formed with a gate insulating film 16 interposed therebetween. Sidewall insulating films 20 are formed on sidewall portions of the gate electrode 18.

Source/drain diffusion layers 22 are formed at two sides of the gate electrode 18 provided with the sidewall insulating films 20.

Silicide layers 24a and 24b are formed on an upper portion of the gate electrode 18 and on the source/drain diffusion layers 22, respectively. The silicide layers 24b on the source/drain diffusion layers 22 function as source/drain electrodes.

Accordingly, a transistor 26 including the gate electrode 18 and the source/drain diffusion layers 22 is formed.

An insulating film (oxidation preventing insulating film) 28 is formed on the semiconductor substrate 10 on which the transistor 26 is formed. The thickness of the insulating film 28 is set, for example, to 200 nm. As the insulating film 28, for example, a silicon oxynitride film (SiON film) is used.

An interlayer insulating film 30 is formed on the semiconductor substrate 10 on which the insulating film 28 is formed. The distance from the surface of the semiconductor substrate 10 to the surface of the interlayer insulating film 30 is set, for example, to 785 nm. As the interlayer insulating film 30, for example, a silicon oxide film is used. The surface of the interlayer insulating film 30 is planarized.

Contact holes 32 reaching the source/drain electrodes 24b are formed in the interlayer insulating film 30 and the insulating film 28.

An adhesive film 34 is formed in each contact hole 32. As the adhesive film 34, for example, a laminate film containing a Ti film and a TiN film, which are sequentially laminated to each other, is used. The thickness of the Ti film is set, for example, to 30 nm. The thickness of the TiN film is set, for example, to 20 nm.

A conductive plug 36 is filled in each contact hole 32 in which the adhesive film 34 is formed. As a material for the conductive plug 36, for example, tungsten (W) is used.

On the interlayer insulating film 30 in which the conductive plugs 36 are buried, for example, a silicon oxynitride film 38 is formed. The thickness of the silicon oxynitride film 38 is set, for example, to 100 nm.

On the silicon oxynitride film 38, for example, a silicon oxide film 40 is formed. The thickness of the silicon oxide film 40 is set, for example, to 130 nm.

The silicon oxynitride film 38 and the silicon oxide film 40 collectively form an interlayer insulating film 42. The interlayer insulating film 42 is a film to prevent upper surfaces of the conductive plugs 36 being oxidized after the conductive plugs 36 are buried in the interlayer insulating film 30.

In this embodiment, although the case in which the laminate film of the silicon oxynitride film 38 and the silicon oxide film 40 is formed as the interlayer insulating film 42 is described by way of example, the interlayer insulating film 42 is not limited to the laminate film of the silicon oxynitride film 38 and the silicon oxide film 40. For example, as the interlayer insulating film 42, a silicon nitride film, an aluminum oxide film, or the like may also be used.

An adhesive film 43 is formed on the interlayer insulating film 42. The adhesive film 43 is a film to ensure the adhesion to an underlayer of a lower electrode 48 which will be described later. As the adhesive film 43, for example, an aluminum oxide (Al₂O₃) film is used. The thickness of the adhesive film 43 is set, for example, to 20 nm.

A conductive film 44 is formed on the adhesive film 43. As the conductive film 44, a noble metal film is used. In more particular, as the conductive film 44, for example, a platinum (Pt) film is used. The thickness of the conductive film 44 is set, for example, to 100 to 150 nm.

In this embodiment, although the case in which a platinum film is used as the conductive film 44 is described by way of example, the conductive film 44 is not limited to a platinum film. As the conductive film 44, for example, an iridium film, a ruthenium film, a ruthenium oxide (RuO₂) film, or an SrRuO₃ film may also be used. In addition, a laminate film containing the films mentioned above may also be formed as the conductive film 44.

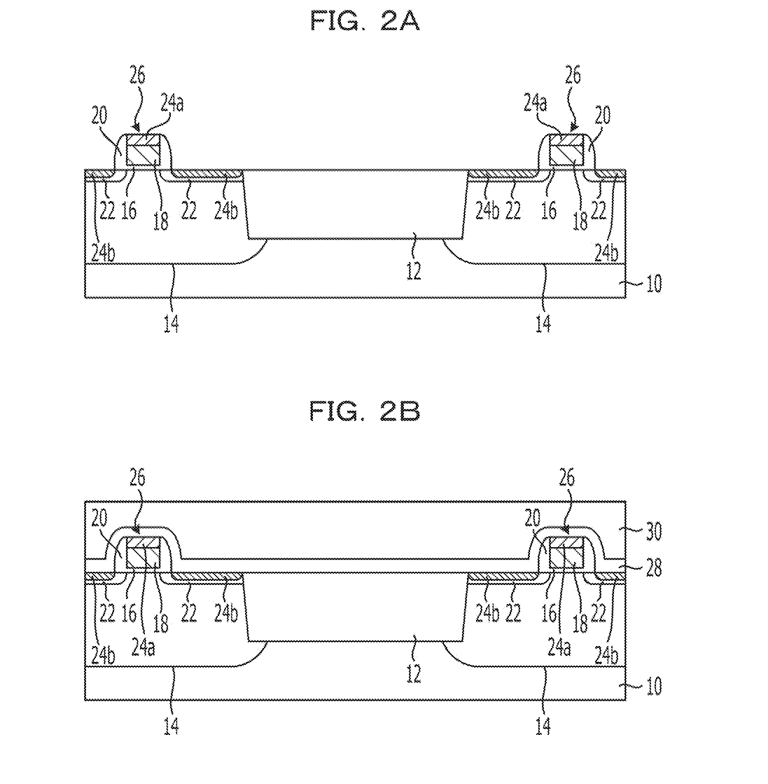

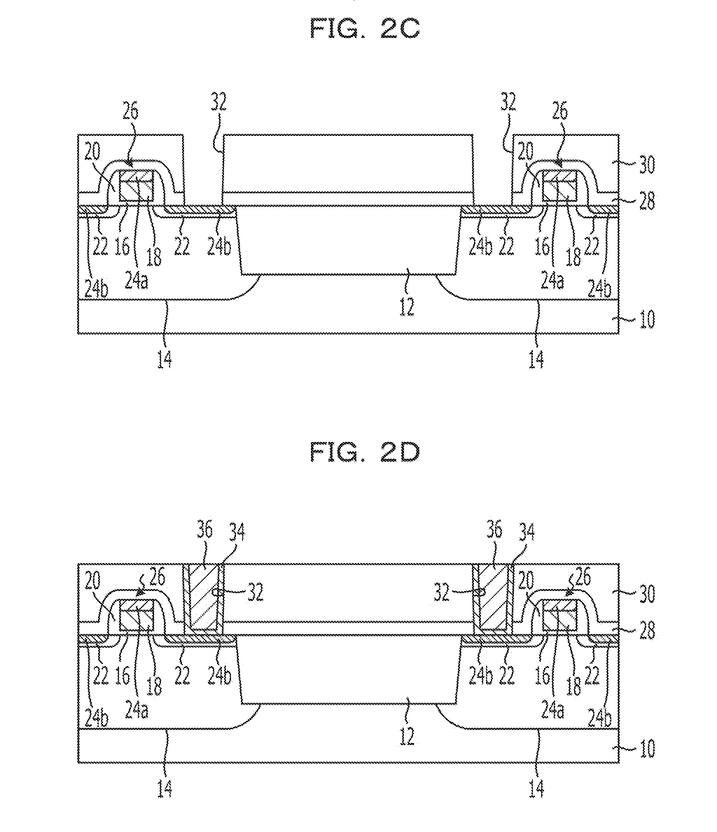

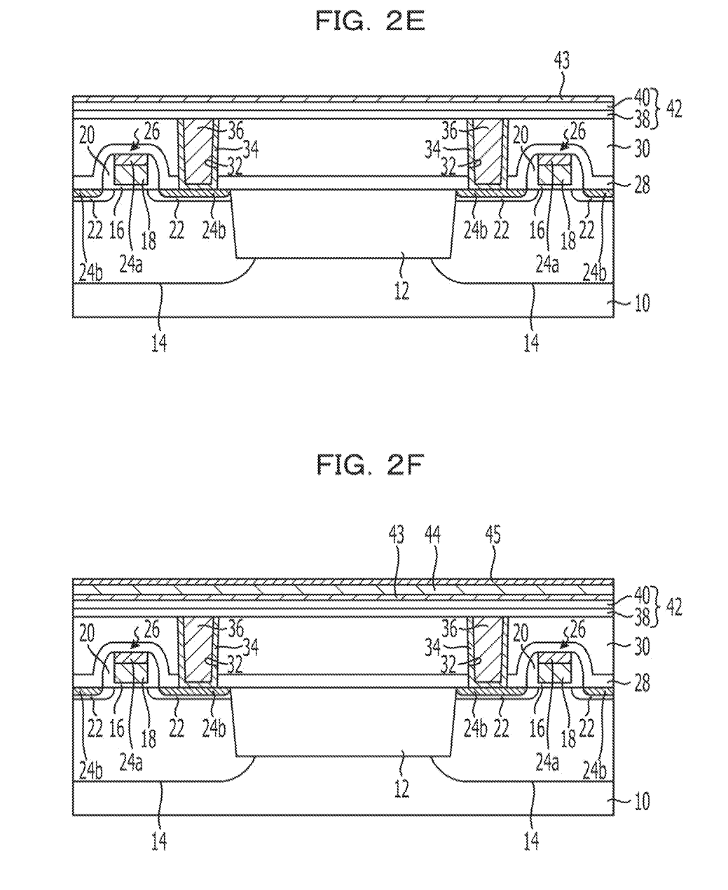

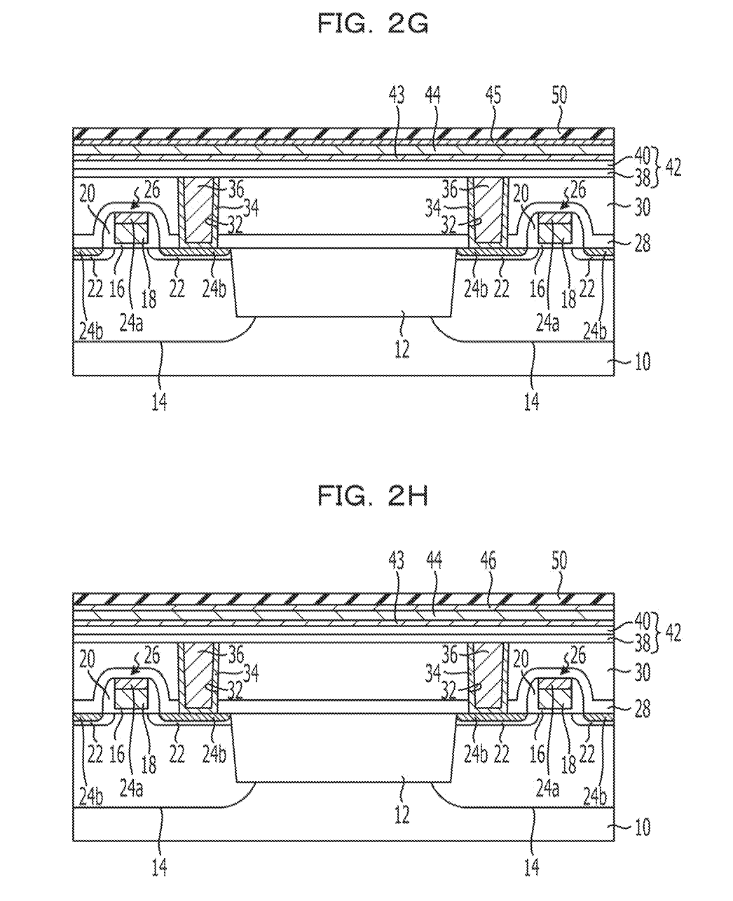

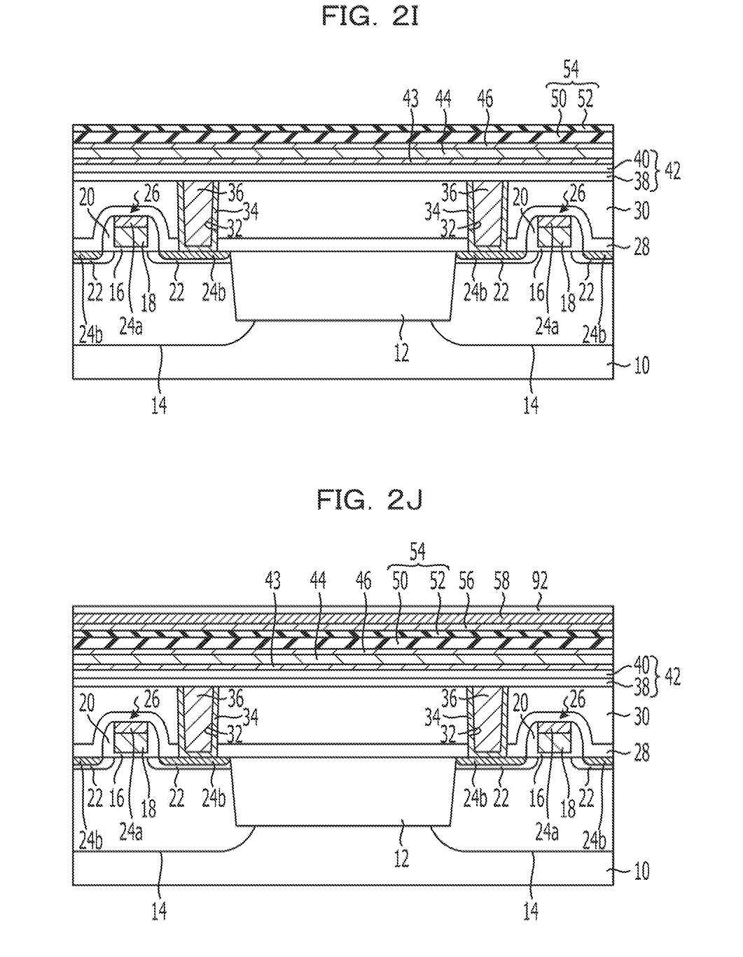

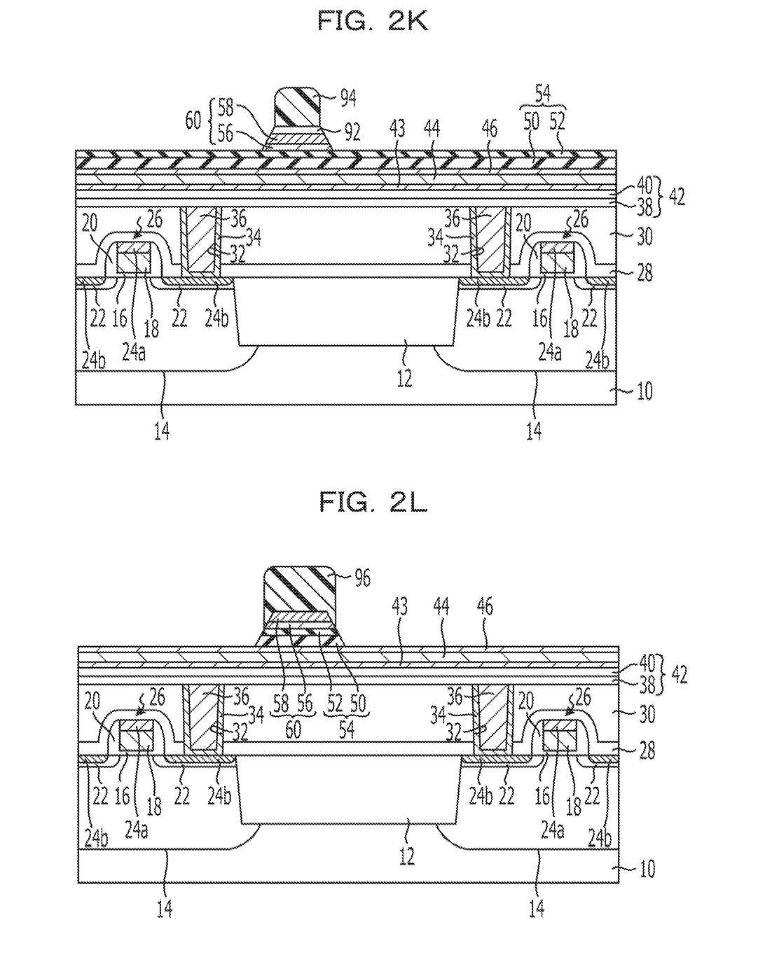

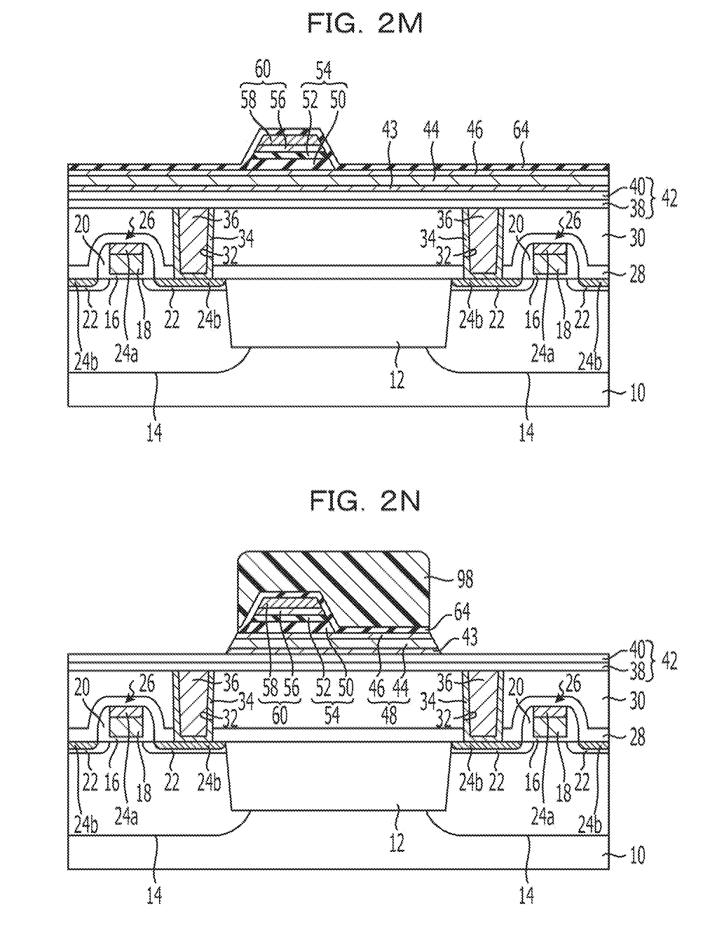

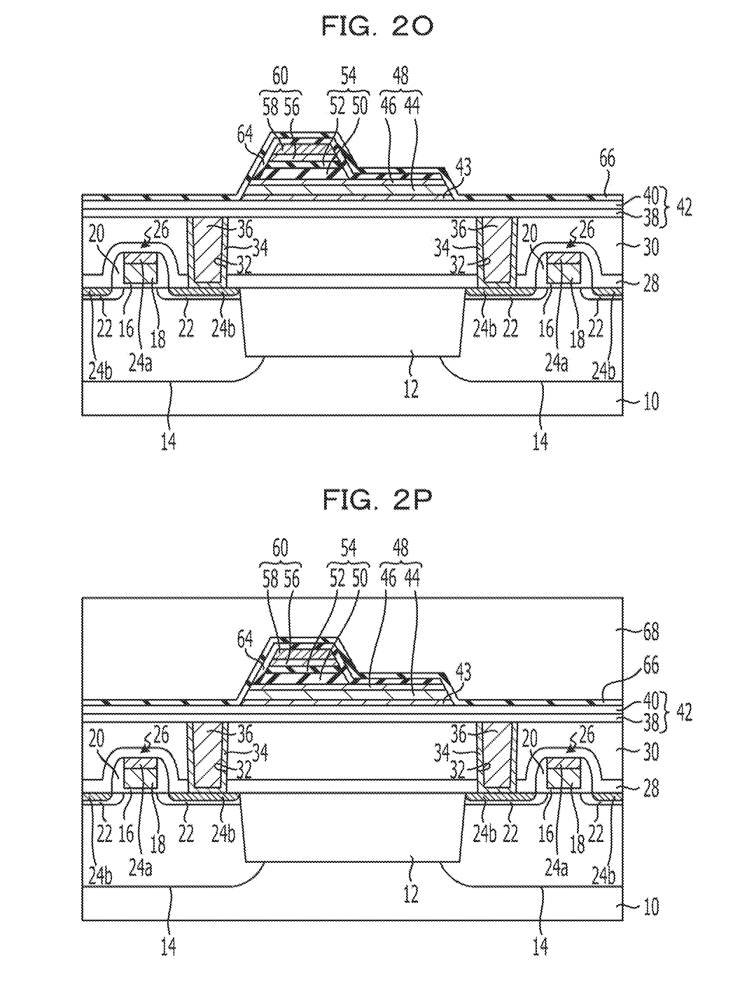

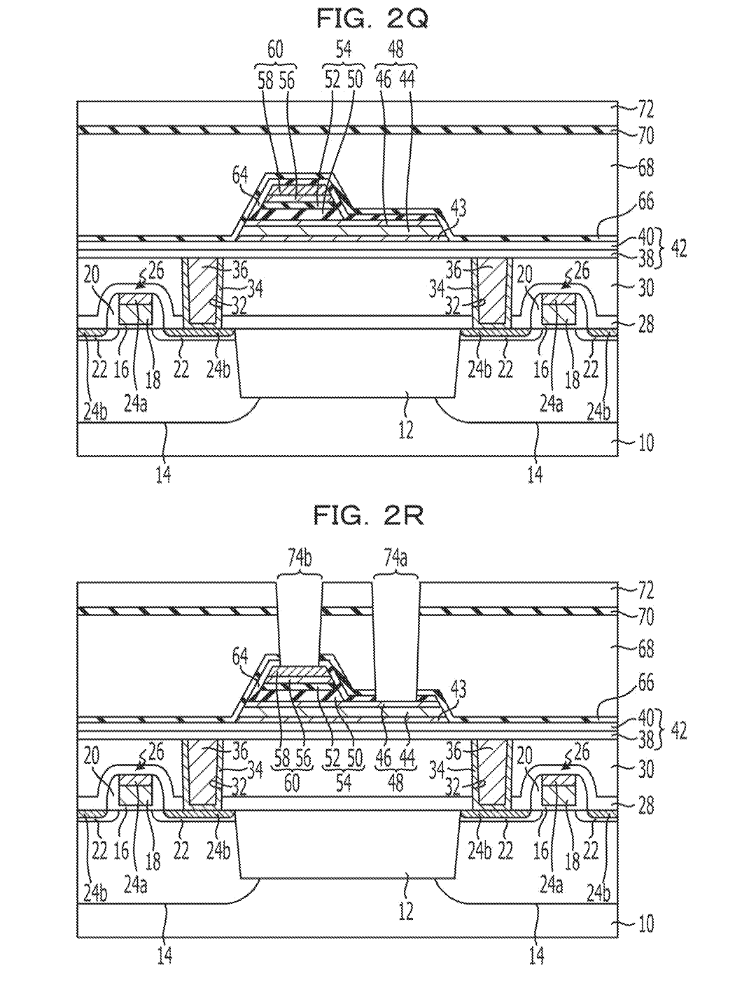

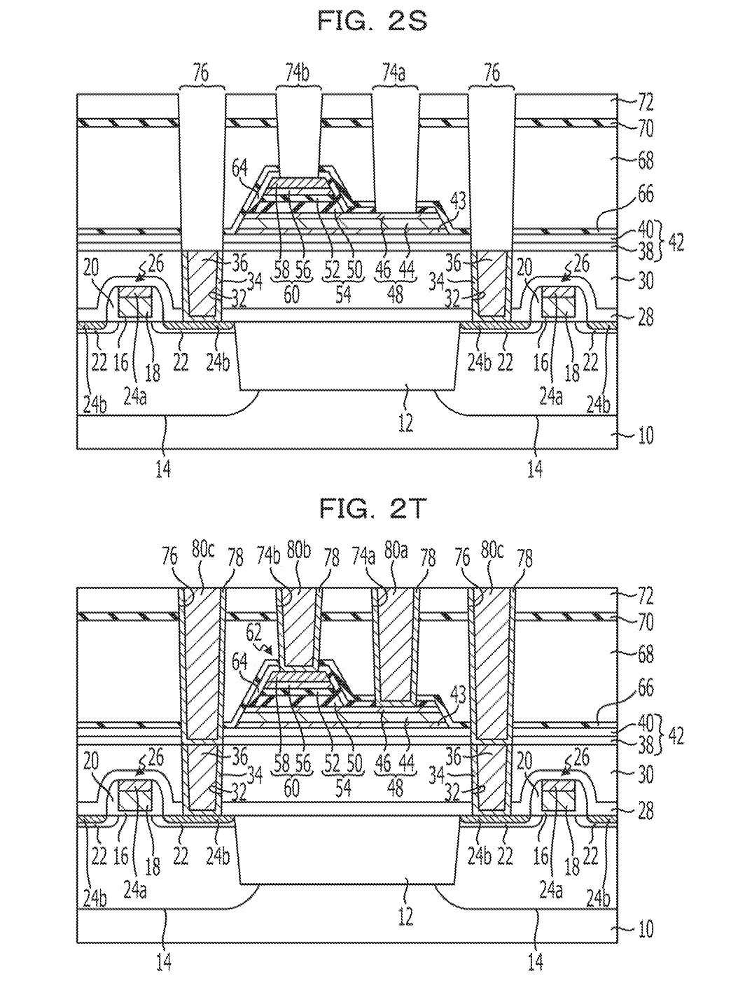

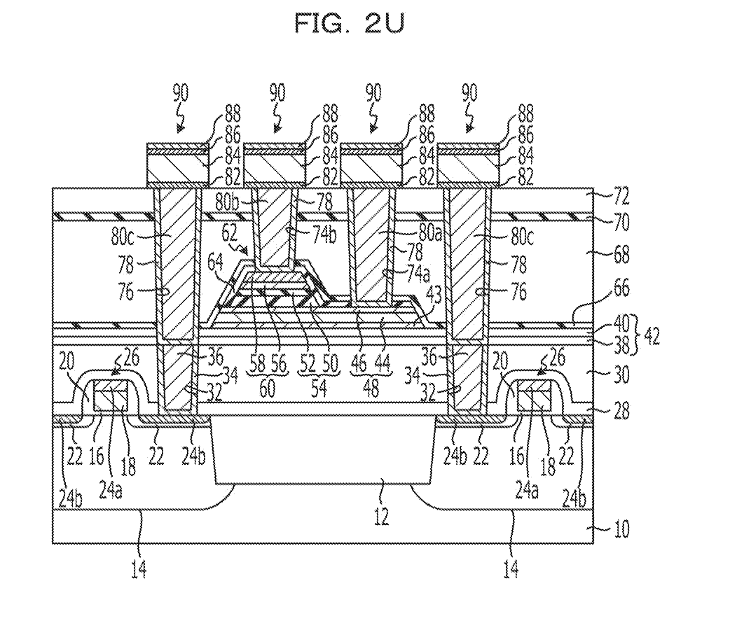

A conductive film 46 is formed on the conductive film 44. The thickness of the conductive film 46 is set, for example, to 0.1 to 3 nm. As the conductive film 46, for example, a noble metal film is used. A noble metal contained in the conductive film 46 is preferably the same element as that of a noble metal contained in the conductive film 44. As described later, when the film formation is performed on the conductive film 44, an amorphous noble metal oxide film 45 is formed (see FIG. 2F). The amorphous noble metal oxide film 45 is reduced, for example, by a heat treatment in a subsequent step into the noble metal film 46. When a noble metal contained in the noble metal oxide film 45 is the same element as that of the noble metal contained in the conductive film 44, the conductive film 46 and the conductive film 44 may not be discriminated from each other in some cases. In addition, since the conductive film 46 is a film obtained by reducing the amorphous noble metal oxide film 45, the diameter of crystal grains of the conductive film 46 may be smaller than that of crystal grains of the conductive film 44 in some cases. When a platinum oxide film (PtO_{X} film) is formed as the amorphous metal oxide film 45, the platinum oxide film is reduced into a platinum film, for example, by a heat treatment in a subsequent step, and as a result, the conductive film 46 which is a platinum film is formed.

When an iridium film is used as the conductive film 44, for example, an iridium film may also be used as the conductive film 46. In this case, the thickness of the iridium film 46 is set, for example, to approximately 10 to 30 nm.

In addition, when ruthenium film is used as the conductive film 44, for example, a ruthenium film may also be used as the conductive film 46. In this case, the thickness of the ruthenium film 46 is set, for example, to approximately 10 to 30 nm.

In addition, when an SrRuO₃ film is used as the conductive film 44, the conductive film 46 may not be formed.

In addition, when a platinum film, an iridium film, or a ruthenium film is used as the conductive film 44, as the conductive film 46, an SrRuO₃ film, a LaSrCoO₃ film, or the like may also be used. In this case, the thickness of the conductive film 46 of SrRuO₃ or LaSrCoO₃ is preferably set to approximately 1 to 5 nm.

Accordingly, the lower electrode 48 of a capacitor 62 is formed from the conductive film 44 and the conductive film 46.

A ferroelectric film 50 is formed on the lower electrode 48. The ferroelectric film 50 is a film formed, for example, by a sputtering method. As the ferroelectric film 50, for example, lead zirconate titanate added with La, that is, a PZT (PbZrₓTi₁₋ₓO₃) film (0≦x≦1) added with La, is used. A PZT film added with La is called a PLZT film. A PZT film is a ferroelectric film having a perovskite structure. A PZT film added with La is also a ferroelectric film having a perovskite structure. The ferroelectric film 50 is crystallized, for example, by a heat treatment which will be described later.

A capacitor dielectric film 54 of the capacitor 62 is formed from the ferroelectric film 50 and a ferroelectric film 52 which will be described later. When the thickness of the ferroelectric film 50 is too large, the ratio of the ferroelectric film 50 to the capacitor dielectric film 54 becomes relatively too high, and as a result, electrical properties of the capacitor 62 obtained by forming the ferroelectric film 52 may not be sufficiently improved. In addition, when the thickness of the ferroelectric film 50 is too large, and the thickness of the capacitor dielectric film 54 is also too large, a low-voltage operation may not be easily performed. On the other hand, when the thickness of the ferroelectric film 50 is too small, a capacitor 62 having excellent electrical properties may not be obtained. Hence, the thickness of the ferroelectric film 50 is set, for example, to approximately 30 to 150 nm. More preferably, the thickness of the ferroelectric film 50 is set, for example, to approximately 50 to 120 nm. In this embodiment, the thickness of the ferroelectric film 50 is set, for example, to 90 nm.

In this embodiment, a lead zirconate titanate added with La (PLZT) may be used as a material for the ferroelectric film 50 for the following exemplary reason.

That is, a target of a lead zirconate titanate added with no impurities (PZT) is not easily sintered, and defects (voids) are liable to be generated in the target.

On the other hand, a target added with an impurity is easily sintered, and defects are not likely to be generated in the target. Hence, in order to form a ferroelectric film 50 having excellent quality by using a good quality target, an impurity is preferably added to a target.

However, when a ferroelectric film is formed by using a target added with an impurity, the impurity is contained in the ferroelectric film. When the amount of the impurity contained in the ferroelectric film is relatively large, the inversion charge amount of the capacitor 62 is considerably decreased. In this case, the capacitor 62 having excellent electrical properties may not be obtained.

Accordingly, in this embodiment, a PZT film added with a small amount of La is formed as the ferroelectric film 50. La is an impurity which functions to reduce a leak current of a capacitor. In particular, the amount of La added to the ferroelectric film 50 is set to 0.1 to 4.0 mole percent. In this embodiment, the amount of La added to the ferroelectric film 50 is set, for example, to 2.0 mole percent.

Since the amount of La added to the ferroelectric film 50 is set relatively small, the leak current of the capacitor may be reduced without causing a considerable decrease in inversion charge amount.

In addition, in this embodiment, although the case in which the ferroelectric film 50 is formed by a sputtering method is described by way of example, the ferroelectric film 50 is not limited to film formed by a sputtering method. For example, the ferroelectric film 50 may also be formed, for example, by a metal organic chemical vapor deposition (MOCVD) method, a sol-gel method, a metal-organic decomposition (MOD) method, a chemical solution deposition (CSD) method, a CVD method, or an epitaxial growth method.

The ferroelectric film 52 is formed on the ferroelectric film 50. The ferroelectric film 52 is a film formed, for example, by a sputtering method. As a material for the ferroelectric film 52, lead zirconate titanate added with La, Ca, and Sr, that is, a PZT (PbZr_{X}Ti_{1-X}O₃) film (0≦x≦1) added with La, Ca, and Sr is used. A PZT film added with La, Ca, and Sr is called a CSPLZT film. The ferroelectric film 52 is crystallized, for example, by a heat treatment which will be described later.

When the thickness of the ferroelectric film 52 is too large, the ratio of the ferroelectric film 52 to the capacitor dielectric film 54 becomes relatively too high, and as a result, the capacitor 62 having excellent electrical properties may not be obtained. In addition, when the thickness of the ferroelectric film 52 is too large, and the thickness of the capacitor dielectric film 54 is also too large, a low-voltage operation may not be easily performed. On the other hand, when the thickness of the ferroelectric film 52 is too small, the capacitor 62 having excellent electrical properties may not be obtained. Hence, the thickness of the ferroelectric film 52 is set, for example, to approximately 5 to 20 nm.

Sr added to the ferroelectric film 52 functions to retard degradation in hysteresis characteristics caused by imprint. Ca added to the ferroelectric film 52 functions to decrease the coercive electric field of the capacitor 62. La added to the ferroelectric film 52 functions to reduce the leak current of the capacitor 62. In addition, the impurities (La, Sr, and Ca) added to the ferroelectric film 52 enable the interface between the ferroelectric film 52 and an upper electrode 60 to have an excellent condition, and thereby the fatigue characteristics of the capacitor 62 are improved.

However, as described above, when the amount of impurities present in the ferroelectric film is relatively large, the inversion charge amount of the capacitor 62 is considerably decreased. In this case, the capacitor 62 having excellent electrical properties may not be obtained.

Accordingly, in this embodiment, the amounts of La, Sr, and Ca added to the ferroelectric film 52 are set relatively small.

In particular, the amount of La added to the ferroelectric film 52 is set to 0.1 to 4.0 mole percent. In this embodiment, the amount of La added to the ferroelectric film 52 is set, for example, to 2.0 mole percent.

In addition, the amount of Sr added to the ferroelectric film 52 is set to 0.1 to 3.0 mole percent. In this embodiment, the amount of Sr added to the ferroelectric film 52 is set, for example, to 2.0 mole percent.

In addition, the amount of Ca added to the ferroelectric film 52 is set to 0.1 to 6.0 mole percent. In this embodiment, the amount of Ca added to the ferroelectric film 52 is set, for example, to 5.0 mole percent.

The total amount of the impurities (La, Sr, and Ca) added to the ferroelectric film 52 is set to 10.0 mole percent or less. The total amount of the impurities (La, Sr, and Ca) added to the ferroelectric film 52 is set to 10.0 mole percent or less for the following exemplary reason. That is, if the total amount of the impurities added to the ferroelectric film 52 is too large, when the ferroelectric film 52 is crystallized, crystal grains of the ferroelectric film 50 and crystal grains of the ferroelectric film 52 are not continuously formed. When the crystal grains of the ferroelectric film 50 and the crystal grains of the ferroelectric film 52 are not continuously formed, an interfacial layer is generated at the interface between the ferroelectric films 50 and 52, and as a result, the capacitor 62 having excellent electrical properties may not be obtained. By the exemplary reason described above, the total amount of the impurities (La, Sr, and Ca) added to the ferroelectric film 52 is set to 10.0 mole percent or less.

In this embodiment, although the case in which the ferroelectric film 52 is formed by a sputtering method is described by way of example, the ferroelectric film 52 is not limited to a film formed by a sputtering method. For example, the ferroelectric film 52 may also be formed, for example, by an MOCVD method, a sol-gel method, an MOD method, a CSD method, a CVD method, or an epitaxial growth method.

In addition, in order to continuously form the crystal grains of the ferroelectric film 50 and the crystal grains of the ferroelectric film 52, a primary material of the ferroelectric film 50 is preferably the same as a primary material of the ferroelectric film 52. In this embodiment, the primary material indicates a material other than the impurities (La, Sr, and Ca) added to the ferroelectric films 50 and 52.

Accordingly, the capacitor dielectric film 54 is formed from the ferroelectric films 50 and 52.

A conductive film 56 is formed on the capacitor dielectric film 54. The conductive film 56 is a film formed, for example, by a sputtering method. The conductive film 56 is a film crystallized when it is formed. As the conductive film 56, for example, an iridium oxide film is used. An Oxygen composition ratio X of an iridium oxide film (IrO_{X} film) used as the conductive film 56 is set, for example, to satisfy 0<X<2. The thickness of the conductive film 56 is preferably set, for example, to approximately 10 to 70 nm. More preferably, the thickness of the conductive film 56 is set to approximately 20 to 50 nm. In this embodiment, the thickness of the conductive film 56 is set, for example, to approximately 50 nm.

A conductive film 58 is formed on the conductive film 56. The conductive film 58 is a film formed, for example, by a sputtering method. As the conductive film 58, for example, an iridium oxide film is used. An Oxygen composition ratio Y of an iridium oxide film (IrO_{Y} film) used as the conductive film 58 is set, for example, to satisfy 0<Y≦2. The oxygen composition ratio Y of the iridium oxide film (IrO_{Y} film) used as the conductive film 58 is preferably higher than the oxygen composition ratio X of the iridium oxide film (IrO_{X} film) used as the conductive film 56. That is, the degree of oxidation of the iridium oxide film used as the conductive film 58 is preferably higher than that of the iridium oxide film used as the conductive film 56. An exemplary reason that the oxygen composition ratio Y of the conductive film 58 is set higher than the oxygen composition ratio X of the conductive film 56 is that when the oxygen composition ratio Y is set high, a hydrogen barrier function may be enhanced. When being formed in an amorphous state, the conductive film 58 may have a relatively high oxygen composition ratio Y. Since the conductive film 58 also sufficiently functions as a hydrogen barrier film, the capacitor dielectric film 54 may be substantially prevented from being reduced by hydrogen in a subsequent step.

The thickness of the conductive film 58 is preferably set, for example, to approximately 100 to 300 nm. In this embodiment, the thickness of the conductive film 58 is set, for example, to approximately 200 nm. The conductive film 58 also functions to substantially prevent the capacitor dielectric film 54 from being damaged, for example, by etching which is performed after the capacitor 62 is formed.

The upper electrode 60 of the capacitor 62 is formed from the conductive films 56 and 58.

Accordingly, the capacitor 62 having the lower electrode 48, the capacitor dielectric film 54, and the upper electrode 60 is formed.

A protective film (hydrogen diffusion-preventing film) 64 is formed on the capacitor 62 so as to cover the capacitor dielectric film 54 and the upper electrode 60. The protective film 64 is a film to substantially prevent the capacitor dielectric film 54 being reduced by hydrogen, moisture, and the like. As the protective film 64, for example, an aluminum oxide film is used. The thickness of the protective film 64 is set, for example, to approximately 20 to 50 nm.

A protective film (hydrogen diffusion-preventing film) 66 is formed on the interlayer insulating film 42 and the capacitor 62 provided with the protective film 64. The protective film 66 is a film to substantially prevent the capacitor dielectric film 54 being reduced by hydrogen, moisture, and the like in cooperation with the protective film 64. As the protective film 66, for example, an aluminum oxide film is used. The thickness of the protective film 66 is set, for example, to approximately 20 nm.

An interlayer insulating film 68 is formed on the protective film 66. As the interlayer insulating film 68, for example, a silicon oxide film is used. The thickness of the interlayer insulating film 68 is set, for example, to approximately 1.4 μm. The surface of the interlayer insulating film 68 is planarized.

A protective film (hydrogen diffusion-preventing film) 70 is formed on the interlayer insulating film 68. As the protective film 70, for example, an aluminum oxide film is used. The thickness of the protective film 70 is set, for example, to approximately 20 to 50 nm. As is the case of the protective films 64 and 66, the protective film 70 is a film to substantially prevent the capacitor dielectric film 54 from being reduced by hydrogen, moisture, and the like. Since being formed on the planarized interlayer insulating film 68, the protective film 70 is formed flat.

An interlayer insulating film 72 is formed on the protective film 70. As the interlayer insulating film 72, for example, a silicon oxide film is used. The thickness of the interlayer insulating film 72 is set, for example, to approximately 300 nm.

A contact hole 74a reaching the lower electrode 48 of the capacitor 62 is formed in the interlayer insulating film 72, the protective film 70, the interlayer insulating film 68, the protective film 66, and the protective film 64.

In addition, a contact hole 74b reaching the upper electrode 60 of the capacitor 62 is formed in the interlayer insulating film 72, the protective film 70, the interlayer insulating film 68, the protective film 66, and the protective film 64.

In addition, contact holes 76 reaching the conductive plugs 36 are formed in the interlayer insulating film 72, the protective film 70, the interlayer insulating film 68, the protective film 66, and the interlayer insulating film 42.

An adhesive film 78 is formed in each of the contact holes 74a, 74b, and 76. As the adhesive film 78, for example, a TiN film is used. The thickness of the adhesive film 78 is set, for example, to approximately 50 to 150 nm.

In the contact holes 74a, 74b, and 76 provided with the adhesive films 78, conductive plugs 80a to 80c are filled, respectively. As a material for the conductive plugs 80a to 80c, for example, tungsten is used.

Wires 90 are formed on the interlayer insulating film 72 in which the conductive plugs 80a to 80c are buried. The wire 90 is formed, for example, by sequentially laminating a TiN film 82, an AlCu alloy film 84, a Ti film 86, and a TiN film 88. The thickness of the TiN film 82 is set, for example, to 50 nm. The thickness of the AlCu alloy film 84 is set, for example, to 550 nm. The thickness of the Ti film 86 is set, for example, to 5 nm. The thickness of the TiN film 88 is set, for example, to 50 nm.

Furthermore, a plurality of layers each containing an interlayer insulating film (not illustrated), at least one conductive plug (not illustrated), at least one wire (not illustrated), and the like is formed on the interlayer insulating film 72 on which the wires 90 are formed.

As a result, the semiconductor device according to this embodiment is formed.

As described above, in this embodiment, the capacitor dielectric film 54 is formed from the PLZT ferroelectric film 50 and the CSPLZT ferroelectric film 52. According to this embodiment, since PLZT is used as the ferroelectric film 50, and the PLZT ferroelectric film 50 is also formed to have a relatively large thickness, the leak current of the capacitor 62 may be sufficiently reduced. Furthermore, according to this embodiment, since CSPLZT is used as the ferroelectric film 52, the capacitor 62 may be obtained so that the hysteresis characteristics are not so much degraded by imprint, the coercive electric field is small, and the fatigue characteristics are excellent. Hence, according to this embodiment, a semiconductor device including the capacitor 62 which is excellent in properties may be provided.

Next, the method for manufacturing the semiconductor device according to this embodiment will be described with reference to FIGS. 2A to 2U. FIGS. 2A to 2U are cross-sectional views illustrating the method for manufacturing the semiconductor device according to this embodiment.

First, as illustrated in FIG. 2A, the element isolation region 12 defining an element region is formed in the semiconductor substrate 10, for example, by a shallow trench isolation (STI) method. As the semiconductor substrate 10, for example, an N-type or a P-type silicon substrate is used. In addition, the method for forming the element isolation region 12 is not limited to an STI method. For example, the element isolation region 12 may also be formed by a local oxidation of silicon (LOCOS) method.

Next, a dopant is implanted by an ion implantation method, so that the well 14 is formed. As the dopant, for example, a P-type dopant is used. As the P-type dopant, for example, boron (B) is used. When a P-type dopant is used as the dopant, the well 14 is formed to have a p-type conductivity.

Next, the gate insulating film 16 is formed on the element region by a thermal oxidation method or the like. The thickness of the gate insulating film 16 is set, for example, to approximately 6 to 7 nm.

Next, a polysilicon film 18 is formed, for example, by a chemical vapor deposition (CVD) method. The thickness of the polysilicon film 18 is set, for example, to approximately 200 nm. The polysilicon film 18 is used as the gate electrode (word line).

In this embodiment, although the case in which the polysilicon film 18 is formed as a film formed into the gate electrode is described by way of example, the film formed into the gate electrode is not limited to a polysilicon film. As the film formed into the gate electrode, for example, a laminate film of an amorphous silicon film and a tungsten silicide film may also be used. When the laminate film of an amorphous silicon film and a tungsten silicide film is formed, the thickness of the amorphous silicon film is set, for example, to approximately 50 nm, and the thickness of the tungsten silicide film is set, for example, to approximately 150 nm.

Next, the polysilicon film 18 is patterned by a photolithographic technique. Accordingly, the gate electrode (word line) 18 is formed from the polysilicon film.

Next, a dopant is implanted, for example, by an ion implantation method in the semiconductor substrate 10 at the two sides of the gate electrode 18 using the gate electrode 18 as a mask. As the dopant, for example, an N-type dopant is used. As the N-type dopant, for example, phosphorus (P) is used. As a result, extension regions (not illustrated) forming shallow regions of extension source/drain are formed.

Next, an insulating film is formed on the entire surface by a CVD method or the like. As the insulating film, for example, a silicon oxide film is formed. The thickness of the insulating film is set, for example, to approximately 300 nm.

Next, anisotropic etching is performed on the insulating film. Accordingly, the sidewall insulating films 20 are formed on the sidewall portions of the gate electrode 18.

Subsequently, by using the gate electrode 18 provided with the sidewall insulating films 20 as a mask, a dopant is implanted in the semiconductor substrate 10 at the two sides of the gate electrode 18 by an ion implantation method or the like. As the dopant, for example, an N-type dopant is used. As the N-type dopant, for example, arsenic (As) is used. As a result, impurity diffusion layers (not illustrated) forming deep regions of the extension source/drain are formed. The source/drain diffusion layers 22 are formed from the extension regions and the deep impurity diffusion layers.

Next, a high melting point metal film (not illustrated) is formed on the entire surface by a sputtering method or the like. As the high melting point metal film, for example, a cobalt film is formed.

Subsequently, a heat treatment is performed to cause a reaction between an upper portion of the gate electrode 18 and the high melting point metal film as well as a reaction between a surface layer portion of the semiconductor substrate 10 and the high melting point metal film.

Next, an unreacted high melting point metal film is removed by wet etching or the like.

Accordingly, for example, the source/drain electrodes 24b of cobalt silicide are formed on the source/drain diffusion layers 22. In addition, for example, the silicide layer 24a of cobalt silicide is formed on the upper portion of the gate electrode 18.

Accordingly, the transistor 26 having the gate electrode 18 and the source/drain diffusion layers 22 is formed.

Subsequently, the insulating film (oxidation preventing film) 28 is formed on the entire surface by a plasma CVD method or the like. As the insulating film 28, for example, a silicon oxynitride film is formed. The thickness of the insulating film 28 is set, for example, to 200 nm.

Next, the interlayer insulating film 30 is formed on the entire surface. The interlayer insulating film 30 is formed, for example, by a plasma CVD method using a TEOS (tetraethoxysilane) gas, that is, by a plasma TEOS CVD method. As the interlayer insulating film 30, for example, a silicon oxide film is formed. The thickness of the interlayer insulating film 30 is set, for example, to 1 μm.

Next, the surface of the interlayer insulating film 30 is planarized, for example, by a chemical mechanical polishing (CMP) method. As a result, the distance from the surface of the semiconductor substrate 10 to the surface of the interlayer insulating film 30 is, for example, approximately 785 nm (see FIG. 2B).

Subsequently, as illustrated in FIG. 2C, the contact holes 32 reaching the source/drain electrodes 24b are formed by a photolithographic technique. The diameter of the contact hole 32 is set, for example, to 0.25 μm.

Next, a Ti film is formed on the entire surface by a sputtering method or the like. The thickness of the Ti film is set, for example, to approximately 30 nm.

Next, a TiN film is formed on the entire surface by a sputtering method or the like. The thickness of the TiN film is set, for example, to approximately 20 nm.

Accordingly, the adhesive film 34 is formed from the Ti film and the TiN film.

Next, a conductive film 36 is formed on the entire surface by a CVD method or the like. As the conductive film 36, for example, a tungsten film is formed. The thickness of the conductive film 36 is set, for example, to approximately 300 nm.

Next, the conductive film 36 and the adhesive film 34 are polished by a CMP method or the like until the surface of the interlayer insulating film 30 is exposed. Accordingly, for example, the conductive plug 36 of tungsten is filled in the contact hole 32 (see FIG. 2D).

Subsequently, as illustrated in FIG. 2E, the silicon oxynitride film 38 is formed on the entire surface by a plasma CVD method or the like. The thickness of the silicon oxynitride film 38 is set, for example, to 100 nm.

Next, the silicon oxide film 40 is formed on the entire surface by a plasma TEOS CVD method or the like. The thickness of the silicon oxide film 40 is set, for example, to 130 nm.

The interlayer insulating film 42 is formed from the silicon oxynitride film 38 and the silicon oxide film 40. The interlayer insulating film 42 is a film to substantially prevent the upper surfaces of the conductive plugs 36 being oxidized after the conductive plugs 36 are buried in the interlayer insulating film 30.

In this embodiment, although the case in which the laminate film of the silicon oxynitride film 38 and the silicon oxide film 40 is formed as the interlayer insulating film 42 is described by way of example, the interlayer insulating film 42 is not limited to the laminate film described above. For example, as the interlayer insulating film 42, a silicon nitride film or an aluminum oxide film may also be formed.

Next, a heat treatment is performed in a nitrogen atmosphere or the like. This heat treatment is performed to discharge gases contained in the interlayer insulating film 42 to the outside (degassing). The substrate temperature in the heat treatment is set, for example, to 650° C. The time for the heat treatment is set, for example, to 30 minutes.

Next, the adhesive film 43 is formed on the entire surface by a sputtering method or the like. The adhesive film 43 is a film to ensure the adhesion to the underlayer of the lower electrode 48 which will be described later. As the adhesive film 43, for example, an aluminum oxide film is formed. The thickness of the adhesive film 43 is set, for example, to 20 nm.

Next, a heat treatment is performed in an oxygen atmosphere by a rapid thermal annealing (RTA) method or the like. The temperature for the heat treatment is set, for example, to 650° C. The time for the heat treatment is set, for example, to 60 seconds.

Subsequently, as illustrated in FIG. 2F, the noble metal film (conductive film) 44 is formed on the entire surface by a sputtering method or the like. The conductive film 44 forms a part of the lower electrode 48 of the capacitor 62. As the conductive film 44, for example, a platinum film is formed. The thickness of the conductive film 44 is set, for example, to approximately 100 to 150 nm. The conductive film 44 is formed, for example, under the following conditions. The substrate temperature is set, for example, to 350° C. As a gas introduced into a film formation chamber, for example, an Ar gas is used. The pressure inside the film formation chamber is set, for example, to 1 Pa. The applied electrical power is set, for example, to 0.3 kW.

In this embodiment, although the case in which a platinum film is formed as the conductive film 44 is described by way of example, the conductive film 44 is not limited to a platinum film. As the conductive film 44, an iridium film, a ruthenium film, a ruthenium oxide (RuO₂) film, an SrRuO₃ film, or the like may also be formed. In addition, the conductive film 44 may also be formed from a laminate film containing the films mentioned above.

Next, the amorphous noble metal oxide film 45 is formed on the entire surface by a sputtering method or the like. The noble metal contained in the noble metal oxide film 45 is preferably the same element as that of the noble metal contained in the conductive film 44. In a subsequent step, the noble metal oxide film 45 is reduced, for example, into the noble metal film 46. The noble metal film 46 formed by reducing the noble metal oxide film 45 forms a part of the lower electrode 48 of the capacitor 62. As the amorphous noble metal oxide film 45, for example, a platinum oxide film (PtO_{X} film) is formed.

In addition, as the amorphous noble metal oxide film 45, for example, an iridium oxide film may also be formed. In this case, the noble metal oxide film 45 of iridium oxide is reduced into an iridium film in a subsequent step.

In addition, as the noble metal oxide film 45, for example, an SrRuO₃ film or a LaSrCoO₃ film may also be formed. When an SrRuO₃ film or a LaSrCoO₃ film is formed as the noble metal oxide film 45, the metal oxide film 45 of SrRuO₃ or LaSrCoO₃ is not reduced in a heat treatment in a subsequent step.

In this embodiment, film 45 may be formed for the following exemplary reasons.

First, when the ferroelectric film 50 is directly formed on the noble metal film 44 in which the crystallinity is not sufficiently uniform, the crystallinity of the ferroelectric film 50 may become non-uniform in some cases. On the other hand, when the amorphous noble metal oxide film 45 is formed on the noble metal film 44, and the ferroelectric film 50 is formed on the amorphous noble metal oxide film 45, even if the crystallinity of the noble metal film 44 is not sufficiently uniform, the ferroelectric film 50 may be formed to have uniform crystallinity.

In addition, although a crystal noble metal oxide film is not likely to be reduced, the amorphous noble metal oxide film 45 is relatively easily reduced. Hence, when the amorphous noble metal oxide film 45 is formed, for example, in a heat treatment in a subsequent step, the noble metal oxide film 45 may be changed into the noble metal film 46. The capacitor 62 in which the lower electrode 48 is entirely formed of a noble metal has excellent electrical properties as compared to that of a capacitor in which a noble metal oxide is partially present in the lower electrode 48.

In addition, at the stage at which the ferroelectric film 50 is formed, oxygen vacancies may be generated in the ferroelectric film 50 in some cases. When the noble metal oxide film 45 is formed under the ferroelectric film 50, oxygen is released from the noble metal oxide film 45, for example, in a heat treatment in which the ferroelectric film 50 is crystallized, and the oxygen thus released is supplied to the ferroelectric film 50 from a lower surface side thereof. The oxygen released from the noble metal oxide film 45 compensates for the oxygen vacancies in the ferroelectric film 50. Hence, according to this embodiment, a ferroelectric film 50 having excellent crystallinity may be obtained.

In addition, in the heat treatment in which the ferroelectric film 50 is crystallized, the amorphous noble metal oxide film 45 is able to substantially suppress oxygen in the ferroelectric film 50 from diffusing into the lower electrode 48. Accordingly, when the amorphous noble metal oxide film 45 is formed, the ferroelectric film 50 having excellent crystallinity may be obtained.

By the exemplary reasons described above, in this embodiment, the amorphous noble metal oxide film 45 is formed.

The thickness of the noble metal oxide film 45 is preferably set to 0.1 to 3 nm. The thickness of the noble metal oxide film 45 is set to 0.1 to 3 nm for the following exemplary reasons.

That is, when the thickness of the noble metal oxide film 45 is less than 0.1 nm, since the amount of oxygen released from the noble metal oxide film 45, for example, in the heat treatment in which the ferroelectric film 50 is crystallized is relatively small, the oxygen vacancies in the ferroelectric film 50 may not be sufficiently compensated for. Hence, the thickness of the noble metal oxide film 45 is preferably set to 0.1 nm or more.

On the other hand, when the thickness of the noble metal oxide film 45 is more than 3 nm, the crystallinity of the noble metal film 44 has not sufficient influence on the ferroelectric film 50, and the ferroelectric film 50 having excellent crystallinity may not be obtained in some cases. In addition, for example, in a heat treatment in a subsequent step, the noble metal oxide film 45 is not entirely changed into the noble metal film 46, and as a result, the noble metal oxide film 45 may partially remain in the lower electrode 48 in some cases. When the amorphous noble metal oxide film 45 partially remains in the lower electrode 48, the capacitor 62 having excellent electrical properties may not be obtained in some cases. Hence, the thickness of the noble metal oxide film 45 is preferably set to 3 nm or less.

By the exemplary reasons described above, in this embodiment, the thickness of the noble metal oxide film 45 is set to 0.1 to 3 nm.

The temperature for forming the noble metal oxide film 45 is set, for example, to 100° C. to 400° C. The temperature for forming the noble metal oxide film 45 is set to 100° C. to 400° C. for the following exemplary reasons.

That is, when being formed at a temperature of less than 100° C., the noble metal oxide film 45 has a very low conductivity and becomes similar to an electrical insulating film. Hence, when the noble metal oxide film 45 is formed at a temperature of less than 100° C., the capacitor 62 having excellent electrical properties may be difficult to obtain in some cases. Accordingly, the temperature for forming the noble metal oxide film 45 is preferably set to 100° C. or more.

On the other hand, when the noble metal oxide film 45 is formed at a temperature of more than 400° C., oxygen is dissociated when the noble metal oxide film 45 is formed, and as a result, a noble metal film is formed instead of the noble metal oxide film 45.

By the exemplary reasons described above, the temperature for forming the noble metal oxide film 45 is preferably set to approximately 100° C. to 400° C. In this embodiment, the temperature for forming the noble metal oxide film 45 is set, for example, to 350° C.

An applied voltage for forming the noble metal oxide film 45 is set, for example, to approximately 0.1 to 0.3 W. When the applied voltage is set relatively low, since discharge is not likely to occur, for example, the thickness of the noble metal oxide film 45 is liable to be non-uniform on a wafer surface. On the other hand, when the applied voltage is set relatively high, it becomes difficult to control the thickness of the noble metal oxide film 45. By the exemplary reasons described above, the applied voltage for forming the noble metal oxide film 45 is preferably set, for example, to approximately 0.1 to 0.3 W.

As a gas introduced into a film formation chamber used when the noble metal oxide film 45 is formed, for example, a mixed gas of an Ar gas and an O₂ gas is used. The ratio of the Ar gas in the mixed gas is preferably set, for example, to approximately 80%. An exemplary reason for this is that when the concentration of the O₂ gas in the mixed gas is set relatively high, the film thickness of the noble metal oxide film 45 may become non-uniform in some cases.

The pressure inside the film formation chamber used when the noble metal oxide film 45 is formed is set, for example, to approximately 1 Pa.

In this embodiment, although the case in which a platinum oxide film is formed as the amorphous noble metal oxide film 45 is described by way of example, the amorphous noble metal oxide film 45 is not limited to a platinum oxide film. As the amorphous noble metal oxide film 45, for example, an amorphous iridium oxide (IrO_{X}) film, an amorphous ruthenium oxide (RuO_{X}) film, an amorphous palladium oxide (PdO_{X}) film, an amorphous SrRuO₃ film, or an amorphous LaSrCoO₃ film may also be formed.

In addition, in this embodiment, although the case in which the noble metal oxide film 45 is formed by a sputtering method is described by way of example, the method for forming the noble metal oxide film 45 is not limited to a sputtering method. For example, the noble metal oxide film 45 may also be formed on the surface of the noble metal film 44 in such a way that after the noble metal film 44 is formed, a heat treatment is performed thereon, and the noble metal oxide film 44 thus treated is then held in the air for, for example, 6 hours or more to spontaneously oxidize the surface of the noble metal film 44. Alternatively, the noble metal oxide film 45 may also be formed on the surface of the noble metal film 44 in such a way that after the noble metal film 44 is formed, the semiconductor substrate 10 is held in a box having an oxygen atmosphere to spontaneously oxidize the surface of the noble metal film 44. The temperature in the box described above is set, for example, to 100° C. or less and, in particular, is set to ordinary temperature. When the noble metal oxide film 45 is formed by spontaneous oxidation as described above, the thickness of the noble metal oxide film 45 is extremely small. In particular, the thickness of the noble metal oxide film 45 is, for example, in a range of approximately 0.1 to 0.5 nm.

In addition, in this embodiment, although the case in which the noble metal oxide film 45 is formed to have a thickness of 0.1 to 3 nm is described by way of example, the thickness of the noble metal oxide film 45 is not limited thereto.

For example, when an SrRuO₃ film or a LaSrCoO₃ film is used as the noble metal oxide film 45, the thickness thereof may be set slightly larger than that described above. In particular, the thickness of an SrRuO₃ film or a LaSrCoO₃ film used as the noble metal oxide film 45 is set, for example, to approximately 1 to 10 nm. More preferably, the thickness of an SrRuO₃ film or a LaSrCoO₃ film used as the noble metal oxide film 45 is set, for example, to approximately 3 to 5 nm.

In addition, when an IrO_{X} film or a RuO_{X} film is used as the noble metal oxide film 45, the ferroelectric film 50 is preferably formed by an MOCVD method. When the ferroelectric film 50 is formed by an MOCVD method, the thickness of the noble metal oxide film 45 is preferably set to approximately 10 to 30 nm. An exemplary reason for this is that when the ferroelectric film 50 is formed by an MOCVD method, if the thickness of the noble metal oxide film 45 is relatively small, the diffusion of oxygen from the inside of the ferroelectric film 50 to the lower electrode 48 may not be sufficiently hindered if not prevented. In addition, an exemplary reason for this is that when the ferroelectric film 50 is formed by an MOCVD method, if the thickness of the noble metal oxide film 45 is too large, the ferroelectric film 50 having excellent crystallinity may not be obtained.

Subsequently, as illustrated in FIG. 2G, the ferroelectric film (first ferroelectric film) 50 is formed on the entire surface by a sputtering method or the like. In more particular, the ferroelectric film 50 is formed by a high frequency sputtering method. The ferroelectric film 50 forms a part of the capacitor dielectric film 54 of the capacitor 62.

As the ferroelectric film 50, lead zirconate titanate added with La, that is, a PZT film (PbZr_{X}Ti_{1-X}O₃ film) (0≦X≦1) added with La, is used. The PZT film added with La is called a PLZT film.

As a target used when the ferroelectric film 50 is formed by a sputtering method, a PLZT target is used.

When the thickness of the ferroelectric film 50 is too large, the ratio of the ferroelectric film 50 in the capacitor dielectric film 54 is relatively too large, and hence an improvement in electrical properties of the capacitor 62 may not be sufficiently obtained by the formation of the ferroelectric film 52. In addition, when the thickness of the ferroelectric film 50 is too large, and the thickness of the capacitor dielectric film 54 is too large, a low-voltage operation may not be easily performed. On the other hand, when the thickness of the ferroelectric film 50 is too small, the capacitor 62 having excellent electrical properties may not be obtained. Hence, the thickness of the ferroelectric film 50 is set, for example, to approximately 30 to 150 nm. More preferably, the thickness of the ferroelectric film 50 is set, for example, to approximately 50 to 120 nm. In this embodiment, the thickness of the ferroelectric film 50 is set, for example, to 90 nm.

In this embodiment, an exemplary reason the ferroelectric film 50 is formed by a sputtering method is that, in order to obtain a capacitor dielectric film 54 having excellent crystallinity, abnormal oxidation is inhibited on the surface of the noble metal oxide film 45.

The temperature for forming the ferroelectric film 50 is preferably set, for example, to 30° C. to 100° C. The temperature for forming the ferroelectric film 50 is set to 30° C. to 100° C. for the following exemplary reasons.

That is, when the temperature for forming the ferroelectric film 50 is set to less than 30° C., the thickness thereof may become non-uniform on a wafer surface in some cases. In addition, when the temperature for forming the ferroelectric film 50 is set to less than 30° C., variation in the (100) orientation is increased, and the crystallinity may become non-uniform in some cases.

On the other hand, when the temperature for forming the ferroelectric film 50 is set to more than 100° C., since the ratios of the (101) orientation and the (100) orientation are increased in the ferroelectric film 50, and the ratio of the (111) orientation is decreased, the capacitor 62 having excellent electrical properties may not be easily obtained in some cases.

By the exemplary reasons described above, in this embodiment, the temperature for forming the ferroelectric film 50 is set to 30° C. to 100° C. In this embodiment, the temperature for forming the ferroelectric film 50 is set, for example, to 50° C.

In this embodiment, lead zirconate titanate (PZT) added with La is used as the ferroelectric film 50 for the following exemplary reasons.

That is, a target of lead zirconate titanate (PZT) added with no impurities is not easily sintered, and defects (voids) are liable to be generated in the target.

On the other hand, a target of lead zirconate titanate (PZT) added with an impurity is easily sintered, and defects are not easily generated in the target. Hence, in order to form the ferroelectric film 50 having excellent quality by using a good quality target, an impurity is preferably added to the target.

However, when a ferroelectric film is formed using a target added with an impurity, the impurity is contained in the ferroelectric film. When the amount of the impurity contained in the ferroelectric film is relatively large, the inversion charge amount of the capacitor 62 is considerably decreased. In this case, the capacity 62 having excellent electrical properties may not be obtained.

Accordingly, in this embodiment, a PZT film added with a small amount of La is used as the ferroelectric film 50. In particular, the amount of La added to the ferroelectric film 50 is set to 0.1 to 4.0 mole percent. In this case, the amount of La added to the ferroelectric film 50 is set, for example, to 2.0 mole percent.

Since the amount of La added to the ferroelectric film 50 is set relatively small, the leak current may be reduced without causing a considerable decrease in inversion charge amount.

In addition, in this embodiment, although the case in which the ferroelectric film 50 is formed by a sputtering method is described by way of example, the method for forming the ferroelectric film 50 is not limited to a sputtering method. The ferroelectric film 50 may also be formed by an MOCVD method, a sol-gel method, an MOD method, a CSD method, a CVD method, an epitaxial growth method, or the like.

In addition, at the stage at which the ferroelectric film 50 is formed by a sputtering method, the ferroelectric film 50 is not crystallized but is in an amorphous state.

Next, by an RTA method or the like, the ferroelectric film 50 is crystallized in an atmosphere containing oxygen. In more particular, in a mixed gas atmosphere containing an inert gas and an oxygen gas, the ferroelectric film 50 is processed by a heat treatment. As the inert gas, for example, an argon gas is used.

The heat treatment is performed under the following conditions. The time for the heat treatment is set, for example, to 90 seconds.

In order to uniformly crystallize the ferroelectric film 50 on a wafer surface, the flow rate of an argon gas for the heat treatment is preferably set to 1,500 sccm or more. In this embodiment, the flow rate of an argon gas is set, for example, to 1,960 sccm.

The setting of the flow rate of an oxygen gas for the heat treatment is significantly important. When the flow rate of an oxygen gas is too high, the ratio of the (100) orientation of the ferroelectric film 50 is increased, and the ratio of the (111) orientation is decreased; hence, the capacitor 62 having excellent electrical properties may not be easily obtain in some cases. When the flow rate of an oxygen gas is too low, oxygen vacancies are generated in the ferroelectric film 50, and the ratio of random orientation is increased; hence, the ferroelectric film 50 having excellent crystallinity may not be obtained in some cases. Accordingly, the flow rate of an oxygen gas is preferably set to 10 to 100 sccm. When the thickness of the ferroelectric film 50 is small, the flow rate of an oxygen gas is set slightly lower, so that the crystallinity of the ferroelectric film 50 is improved. For example, when the thickness of the ferroelectric film 50 is 120 to 150 nm, the flow rate of an oxygen gas is preferably set to 30 to 70 sccm. In addition, when the thickness of the ferroelectric film 50 of PLZT is 50 to 120 nm, the flow rate of an oxygen gas is preferably set to 20 to 50 sccm. In this embodiment, the flow rate of an oxygen gas is set, for example, to 25 sccm.

When PLZT is used as a material for the ferroelectric film 50, the temperature for the heat treatment (substrate temperature) is set, for example, to 550° C. to 650° C. The temperature for the heat treatment has an influence on the crystallinity of the ferroelectric film 50 and consequently has an influence on the electrical properties of the capacitor 62. Since the crystallization temperature of the ferroelectric film 50 of PLZT is approximately 550° C., the temperature for the heat treatment is preferably set to 550° C. or more. On the other hand, when the temperature for the heat treatment is too high, since the size of crystal grains of PLZT in the ferroelectric film 50 excessively increases, the inversion charge amount Q_{SW} may be decreased, and/or the leak current may be increased. Hence, the temperature for the heat treatment of the ferroelectric film 50 of PLZT is preferably set to 650° C. or less. In this embodiment, the temperature for the heat treatment performed when the ferroelectric film 50 is crystallized is set, for example, to 620° C.

In addition, when being formed by an MOCVD method, the ferroelectric film 50 is deposited in a crystallized state, and hence the heat treatment to crystallize the ferroelectric film 50 is not required.

However, when the ferroelectric film 50 is formed by an MOCVD method, carbon and/or organic substances may exist on the surface of the ferroelectric film 50 in some cases. Hence, a heat treatment to sufficiently remove the carbon and/or organic substances mentioned above is preferably performed. As in the case of the heat treatment performed when the ferroelectric film 50 is formed by a sputtering method, the temperature for this heat treatment is set, for example, to 550° C. to 650° C. In addition, as in the case of the heat treatment performed when the ferroelectric film 50 is formed by a sputtering method, as an atmosphere for this heat treatment, an atmosphere containing oxygen may be used. In more particular, a mixed gas atmosphere containing an oxygen gas and an argon gas is used.

Since the ferroelectric film 50 is formed on the amorphous noble metal oxide film 45 and is then crystallized by a heat treatment, even when the crystallinity of the noble metal film 44 is not sufficiently uniform, a ferroelectric film 50 having uniform crystallinity may be obtained. In addition, by this heat treatment, the amorphous noble metal oxide film 45 is reduced into the noble metal 46 (see FIG. 2H). In addition, in this heat treatment, oxygen is released from the noble metal oxide film 45. The oxygen released from the noble metal oxide film 45 compensates for oxygen vacancies generated in the ferroelectric film 50. Hence, the ferroelectric film 50 having excellent crystallinity may be obtained. When a platinum oxide film is formed as the noble metal oxide film 45, the noble film (conductive film) 46 which is a platinum film is then formed.

In this embodiment, although the case in which a platinum oxide film is formed as the noble metal oxide film 45 and the conductive film 46 is formed of a platinum film is described by way of example, the conductive film 46 is not limited to a platinum film. For example, when an amorphous iridium oxide (IrO_{X}) film is formed as the noble metal oxide film 45, the iridium oxide film is reduced into an iridium film by a heat treatment, and the conductive film 46 which is the iridium film is formed. In addition, when an amorphous ruthenium oxide (RuO_{X}) film is formed as the noble metal oxide film 45, the ruthenium oxide film is reduced into a ruthenium film by a heat treatment, and the conductive film 46 which is the ruthenium film is formed. In addition, when an amorphous palladium oxide (PdO_{X}) film is formed as the noble metal oxide film 45, the palladium oxide film is reduced into a palladium film by a heat treatment, and the conductive film 46 which is the palladium film is formed. In addition, when an amorphous SrRuO₃ film is formed as the noble metal oxide film 45, the SrRuO₃ film is crystallized by a heat treatment, and the conductive film 46 which is the SrRuO₃ film having a perovskite structure is formed. Furthermore, when an amorphous LaSrCoO₃ film is formed as the noble metal oxide film 45, the LaSrCoO₃ film is crystallized, for example, by a heat treatment, and the conductive film 46 which is the LaSrCoO₃ film having a perovskite structure is formed.

Subsequently, as illustrated in FIG. 2I, the ferroelectric film (second ferroelectric film) 52 is formed on the entire surface by a sputtering method or the like. In more particular, by a high frequency sputtering method, the ferroelectric film 52 is formed. The ferroelectric film 52 is a film forming a part of the capacitor dielectric film 54 of the capacitor 62. As a material for the ferroelectric film 52, lead zirconate titanate added with La, Ca, and Sr, that is, a PZT film added with La, Ca, and Sr, is used. A PZT film added with La, Ca, and Sr is called a CSPLZT film. As illustrated in FIG. 2I, the ferroelectric film 50 and 52 are collectively represented by a dielectric film 54 which will be formed into the capacitor dielectric film 54.

When the thickness of the ferroelectric film 52 is too large, the ratio of the ferroelectric film 52 in the capacitor dielectric film 54 becomes relatively too high, and as a result, the capacitor 62 having excellent electrical properties may not be obtained. In addition, when the thickness of the ferroelectric film 52 is too large, and the thickness of the capacitor dielectric film 54 is too large, a low-voltage operation may not be easily performed. On the other hand, when the thickness of the ferroelectric film 52 is too small, the capacitor 62 having excellent electrical properties may not be obtained. Accordingly, the thickness of the ferroelectric film 52 is set, for example, to approximately 5 to 20 nm.

Sr added to the ferroelectric film 52 functions to retard degradation in hysteresis characteristics caused by imprint. Ca added to the ferroelectric film 52 functions to decrease the coercive electric field of the capacitor 62. La added to the ferroelectric film 52 functions to reduce the leak current of the capacitor 62. In addition, the impurities (La, Sr, and Ca) added to the ferroelectric film 52 enables the interface between the ferroelectric film 52 and the upper electrode 60 to have an excellent condition, and thereby the fatigue characteristics of the capacitor 62 are improved.

However, as described above, when the amount of impurities contained in the ferroelectric film is relatively large, the inversion charge amount of the capacitor 62 is considerably decreased. In this case, the capacitor 62 having excellent electrical properties may not be obtained.

Accordingly, in this embodiment, the amounts of La, Sr, and Ca added to the ferroelectric film 52 are set relatively small.

In particular, the amount of La added to the ferroelectric film 52 is set to 0.1 to 4.0 mole percent. In this embodiment, the amount of La added to the ferroelectric film 52 is set, for example, to 2.0 mole percent.

In addition, the amount of Sr added to the ferroelectric film 52 is set to 0.1 to 3.0 mole percent. In this embodiment, the amount of Sr added to the ferroelectric film 52 is set, for example, to 2.0 mole percent.

In addition, the amount of Ca added to the ferroelectric film 52 is set to 0.1 to 6.0 mole percent. In this embodiment, the amount of Ca added to the ferroelectric film 52 is set, for example, to 5.0 mole percent.

The total amount of the impurities (La, Sr, and Ca) added to the ferroelectric film 52 is set to 10.0 mole percent or less. If the total amount of the impurities added to the ferroelectric film 52 is too large, when the ferroelectric film 52 is crystallized in a heat treatment in a subsequent step, crystal grains of the ferroelectric film 50 and crystal grains of the ferroelectric film 52 are not continuously formed. When the crystal grains of the ferroelectric film 50 and the crystal grains of the ferroelectric film 52 are not continuously formed, an interfacial layer is generated at the interface between the ferroelectric films 50 and 52, and as a result, the capacitor 62 having excellent electrical properties may not be obtained.

In addition, in this embodiment, although the case in which the ferroelectric film 52 is formed by a sputtering method is described by way of example, the method for forming the ferroelectric film 52 is not limited to a sputtering method. For example, the ferroelectric film 52 may also be formed by an MOCVD method, a sol-gel method, an MOD method, a CSD method, a CVD method, an epitaxial growth method, or the like.

In addition, in order to continuously form the crystal grains of the ferroelectric film 50 and the crystal grains of the ferroelectric film 52, a primary material of the ferroelectric film 50 is preferably the same as a primary material of the ferroelectric film 52. In this embodiment, the primary material indicates a material other than the impurities (La, Sr, and Ca) added to the ferroelectric films 50 and 52.

Accordingly, the ferroelectric films 50 and 52 collectively form the dielectric film 54.

Subsequently, as illustrated in FIG. 2J, the conductive film (conductive oxide film) 56 in a crystallized state is formed on the entire surface by a sputtering method or the like. As a target, a target of iridium is used. As a film-forming apparatus, a reactive sputtering apparatus is used. The conductive film 56 forms a part of the upper electrode 60 of the capacitor 62. As the conductive film 56, an iridium oxide film (IrO_{X} film) is formed. In order to sufficiently supply oxygen to the ferroelectric film 52 through the conductive film 56 by a heat treatment in a subsequent step, the thickness of the conductive film 56 is preferably set relatively small. In particular, the thickness of the conductive film 56 is preferably set to approximately 10 to 70 nm. More preferably, the thickness of the conductive film 56 is set to approximately 20 to 50 nm. In this embodiment, the thickness of the conductive film 56 is set, for example, to approximately 50 nm.

The conductive film 56 is formed, for example, under the following conditions. The substrate temperature is set, for example, to 200° C. to 350° C. An exemplary reason the substrate temperature is set to 350° C. or less is that when the film is formed at a substrate temperature of more than 350° C., since abnormal growth is liable to occur, defects are generated at the interface between the upper electrode 60 and the capacitor dielectric film 54, and the capacitor 62 having excellent electrical properties is difficult to obtain. In addition, an exemplary reason the substrate temperature is set to 200° C. or more is that when the film is formed at a substrate temperature of less than 200° C., since the in-plane distribution of the film thickness becomes non-uniform, an excellent crystal condition is not obtained, and the capacitor 62 having excellent electrical properties is not obtained. In this embodiment, the substrate temperature is set to 300° C. The time for the film formation is set, for example, to 8 seconds. The pressure inside a film formation chamber is set, for example, to approximately 2.0 Pa. As a gas introduced into the film formation chamber, for example, a mixed gas of an argon gas and an oxygen gas is used. The flow rate of an argon gas is set, for example, to approximately 140 sccm. The flow rate of an oxygen gas is set, for example, to approximately 60 sccm. A sputtering power is set, for example, to approximately 1 kW.

As described above, when being formed at a relatively high temperature, the conductive film (conductive oxide film) 56 is deposited in a crystallized state.

In addition, the conductive film (conductive oxide film) 56 crystallized as deposited may be formed by forming an iridium oxide conductive film 56 under the following conditions.

That is, the conductive film 56 is formed on the entire surface by a sputtering method or the like. As a target, a target of iridium is used. As a film formation apparatus, a reactive sputtering apparatus is used. An oxygen composition ratio X of an iridium oxide film (IrO_{X} film) formed as the conductive film 56 is set, for example, to satisfy 0<X<2. The thickness of the conductive film 56 is set, for example, to approximately 20 to 75 nm. In this embodiment, the thickness of the conductive film 56 is set to approximately 50 nm. The substrate temperature is set, for example, to approximately 10° C. to 60° C. More preferably, the substrate temperature is set, for example, to 10° C. to 50° C. In this embodiment, the substrate temperature is set to 20° C. A sputtering power is set, for example, to 2 kW. The time for the film formation is set, for example, to 9 seconds. As a gas introduced into a film formation chamber, for example, a mixed gas of an argon gas and an oxygen gas is used. The flow rate of an argon gas is set, for example, to 100 sccm. The flow rate of an oxygen gas is set, for example, to 54 sccm.

When the conductive film 56 of iridium oxide is formed at a relatively low temperature, the resistivity of the conductive film 56 is preferably set in a range of 355 to 418 μΩ·cm. When the resistivity of the conductive film 56 is relatively low, since the number of oxygen vacancies is increased in the conductive film 56, a large amount of Pb in the capacitor dielectric film 54 diffuses into the conductive film 56 in a heat treatment in a subsequent step, and a large number of defects of Pb is generated in the capacitor dielectric film 54. In this case, the inversion charge amount of the capacitor 62 is decreased, and the leak current is increased. On the other hand, when the resistivity of the conductive film 56 is relatively high, a large amount of Ir in the conductive film 56 diffuses into the capacitor dielectric film 54 in a heat treatment in a subsequent step, and as a result, the leak current of the capacitor 62 is unfavorably increased. Hence, the resistivity of the conductive film 56 is preferably set in a range of 355 to 418 μΩ·cm. When the substrate temperature at which the conductive film 56 is formed is set to approximately 10° C. to 50° C., a conductive film 56 having the resistivity as mentioned above may be formed. When the conductive film 56 is formed as described above, the thickness distribution of the conductive film 56 on a wafer surface becomes uniform.

As described above, the conductive film 56 may be formed at a relatively low temperature so as to be in an amorphous state when it is deposited.

Subsequently, a heat treatment is performed in an atmosphere containing oxygen by an RTA method or the like. This heat treatment is performed to crystallize the amorphous ferroelectric film 52 and also to further improve the crystallinity of the ferroelectric film 50. Since the heat treatment is performed after the conductive film 56 is formed, Ir in the conductive film 56 of iridium oxide diffuses into the capacitor dielectric film 54. Hence, Ir is contained in the ferroelectric films 50 and 52. Concomitant with the diffusion of Ir described above, the interface between the capacitor dielectric film 54 and the upper electrode 60 is planarized, and as a result, the electrical properties of the capacitor 62 are improved. In particular, a low-voltage operation of the capacitor 62 may be performed, and the inversion charge amount of the capacitor 62 is increased. The concentrations of Ir contained in the ferroelectric films 50 and 52 are each in a range of approximately 0.01 to 3.0 mole percent. Since the thickness of the conductive film 56 is set relatively small, oxygen is supplied to the ferroelectric film 52 through the conductive film 56, and hence the oxygen vacancies in the ferroelectric film 52 are compensated for. In addition, this heat treatment is performed to improve the adhesion between the conductive film 56 and the ferroelectric film 52. By this heat treatment, peeling of the upper electrode 60 is substantially suppressed, and as a result, an improvement in yield may be realized.

The heat treatment is performed, for example, under the following conditions. When the temperature for the heat treatment is too low, the interfacial state between the ferroelectric film 52 and the upper electrode 60 becomes non-uniform on a wafer surface, the variation in leak current of the capacitor 62 is increased, and the variation in inversion charge amount of the capacitor 62 is also increased. Hence, the substrate temperature for the heat treatment is preferably set, for example, to approximately 700° C. to 740° C. In this embodiment, the substrate temperature is set, for example, to approximately 725° C. The time for the heat treatment is set, for example, to 120 seconds. As an atmosphere in a chamber, a mixed gas atmosphere of an inert gas and an oxygen gas is used. As the inert gas, for example, an argon gas is used. The flow rate of an argon gas is set, for example, to 1,500 to 3,000 sccm. An exemplary reason the flow rate of an argon gas is set to 1,500 sccm or more is that the capacitor dielectric film 54 is uniformly crystallized on a wafer surface. When the flow rate of an oxygen gas is too high, iridium oxide may abnormally grow on the surface of the conductive film 56. On the other hand, when the flow rate of an oxygen gas is too low, deficiency of oxygen occurs in the ferroelectric film 52, and defects are generated. Hence, the flow rate of an oxygen gas is set to approximately 10 to 100 sccm.

Subsequently, the conductive film 58 is formed on the entire surface by a sputtering method or the like. The conductive film 58 forms a part of the upper electrode 60 of the capacitor 62. As the conductive film 58, for example, an iridium oxide film is formed. An oxygen composition ratio Y of an iridium oxide film (IrO_{Y} film) used as the conductive film 58 is set, for example, to satisfy 0<Y≦2. The oxygen composition ratio Y of the iridium oxide film (IrO_{Y} film) used as the conductive film 58 is preferably higher than the oxygen composition ratio X of the iridium oxide film (IrO_{X} film) used as the conductive film 56. An exemplary reason the oxygen composition ration Y of the conductive film 58 is set higher than the oxygen composition ratio X of the conductive film 56 is that when the oxygen composition ratio Y is set higher, a hydrogen barrier function may be enhanced. Since the conductive film 58 also sufficiently functions as a hydrogen barrier film, the capacitor dielectric film 54 may be substantially prevented from being reduced by hydrogen in a subsequent step. The thickness of the conductive film 58 is preferably set, for example, to approximately 100 to 300 nm. In this embodiment, the thickness of the conductive film 58 is set, for example, to approximately 200 nm. The conductive film 58 forms an upper electrode 60 having a sufficient thickness in cooperation with the conductive film 56. Accordingly, since the upper electrode 60 having a sufficient thickness is formed, the capacitor dielectric film 54 may be substantially prevented from being seriously damaged in etching and the like.

The conductive film 58 is formed, for example, under the following conditions. As a gas introduced into a film formation chamber, for example, a mixed gas containing an argon gas and an oxygen gas is used. The flow rate of an argon gas is set, for example, to 100 sccm. The flow rate of an oxygen gas is set, for example, to 100 sccm. The pressure inside the film formation chamber is set, for example, to 0.8 Pa. A sputtering power is set, for example, to 1.0 kW. The time for the film formation is set, for example, to approximately 79 seconds. When the conductive film 58 is formed under these conditions, the thickness of the conductive film 58 is, for example, approximately 200 nm.

The iridium oxide film used as the conductive film 58 preferably has a stoichiometric composition of IrO₂. An exemplary reason for this is that since an iridium oxide film having a stoichiometric composition has no catalytic action on hydrogen, the capacitor dielectric film 54 may be substantially prevented from being reduced by hydrogen.

Next, the bottom surface (rear surface) of the semiconductor substrate 10 is cleaned (backside cleaning). This backside cleaning is different from a general wafer cleaning and is performed to remove particles and the like which are generated when the dielectric film 54 (ferroelectric films 50 and 52) is formed and which are adhered to the rear surface of the wafer.

Next, a protective film 92 is formed on the entire surface by a sputtering method. As the protective film 92, for example, a TiN film is formed. The thickness of the protective film 92 is set, for example, to approximately 34 nm. When the protective film 92 is formed, for example, a target of Ti is used. The substrate temperature for forming the protective film 92 is set, for example, to 200° C. As an atmosphere in a film formation chamber, for example, a mixed gas atmosphere containing an Ar gas and a N₂ gas is used. The flow rate of an Ar gas is set, for example, to 50 sccm. The flow rate of a N₂ gas is set, for example, to 90 sccm. The protective film 92 is a film functioning as a barrier against a reducing substance. Since the protective film 92 functions as a barrier against a reducing substance, the capacitor dielectric film 54 is substantially prevented from being reduced, and hence the electrical properties of the capacitor 62 may be improved. In addition, the protective film 92 also functions as a hard mask which is used when the upper electrode 60 is patterned.

In this embodiment, although the case in which a TiN film is formed as the protective film 92 is described by way of example, the protective film 92 is not limited to a TiN film. As the protective film 92, for example, a TaN film, a TiON film, a TiO_{X} film, a TaO_{X} film, a TaON film, a TiAlO_{X} film, a TaAlO_{X} film, a TiAlON film, a TaAlON film, a TiSiON film, a TaSiON film, a TiSiO_{X} film, a TaSiO_{X} film, an AlO_{X} film, or a ZrO_{X} film may be formed.

Next, a photoresist film 94 is formed on the entire surface by a spin coating method or the like.

Next, the photoresist film 94 is patterned to have a plane shape of the upper electrode 60 using a photolithographic technique.

Next, by using the photoresist film 94 as a mask, the protective film 92, the conductive film 58, and the conductive film 56 are etched. As a result, the upper electrode 60 is formed from the conductive films 56 and 58. When the conductive films 58 and 56 are etched, the protective film 92 functions as a hard mask (see FIG. 2K).

Subsequently, the photoresist film 94 is peeled off. Next, the protective film 92 is removed, for example, by dry etching.

Next, a heat treatment is performed in an atmosphere containing oxygen. This heat treatment is performed to recover the damage done to the capacitor dielectric film 54 (recovering annealing). The temperature for the heat treatment is set, for example, to 600° C. to 700° C. In this embodiment, the temperature for the heat treatment is set to 650° C. The time for the heat treatment is set, for example, to 40 minutes.

Next, a photoresist layer 96 is formed on the entire surface by a spin coating method or the like.

Next, the photoresist film 96 is patterned to have a plane shape of the capacitor dielectric film 54 using a photolithographic technique.

Next, by using the photoresist film 96 as a mask, the dielectric film 54 (the ferroelectric films 50 and 52) is etched, so that the capacitor dielectric film 54 is formed (see FIG. 2L).

Subsequently, the photoresist film 96 is peeled off.

Next, a heat treatment is performed in an oxygen atmosphere. The temperature for the heat treatment is set, for example, to 300° C. to 650° C. The time for the heat treatment is set, for example, to 30 to 120 minutes.

Subsequently, as illustrated in FIG. 2M, the protective film 64 is formed, for example, by a sputtering or a CVD method. As the protective film 64, for example, an aluminum oxide film is formed. The thickness of the protective film 64 is set, for example, to approximately 20 to 50 nm.

Next, a heat treatment is performed in an oxygen atmosphere. The temperature for the heat treatment is set, for example, to 400° C. to 600° C. The time for the heat treatment is set, for example, to 30 to 120 minutes.

Next, a photoresist film 98 is formed on the entire surface by a spin coating method or the like.

Next, the photoresist film 98 is patterned to have a plane shape of the lower electrode 48 by a photolithographic technique.

Next, by using the photoresist film 98 as a mask, the protective film 64, the conductive films 46 and 44, and the adhesive film 43 are etched (see FIG. 2N). The lower electrode 48 is formed from the conductive films 44 and 46. As a result, the capacitor 62 having the lower electrode 48, the capacitor dielectric film 54, and the upper electrode 60 is formed. The protective film 64 remains so as to cover the upper electrode 60 and the capacitor dielectric film 54.

Subsequently, the photoresist film 98 is peeled off.

Next, a heat treatment is performed in an oxygen atmosphere. The temperature for the heat treatment is set, for example, to 300° C. to 400° C. The time for the heat treatment is set, for example, to 30 to 120 minutes.

Subsequently, as illustrated in FIG. 2O, the protective film 66 is formed, for example, by a sputtering or a CVD method. As the protective film 66, for example, an aluminum oxide film is formed. The thickness of the protective film 66 is set, for example, to approximately 20 nm.

Next, a heat treatment is performed in an oxygen atmosphere. This heat treatment is a heat treatment to supply oxygen to the capacitor dielectric film 54 and to improve the electrical properties of the capacity 62. The temperature for the heat treatment is set, for example, to 500° C. to 700° C. The time for the heat treatment is set, for example, to 30 to 120 minutes.

Next, the interlayer insulating film 68 is formed, for example, by a plasma TEOS CVD method. As the interlayer insulating film 68, for example, a silicon oxide film is formed. The thickness of the interlayer insulating film 68 is set, for example, to approximately 1.4 μm.

Next, the surface of the interlayer insulating film 68 is planarized, for example, by a CMP method.

Next, in a plasma atmosphere generated using a N₂O gas or a N₂ gas, a heat treatment is performed. This heat treatment is performed to remove moisture present in the interlayer insulating film 68 and also to change the film quality thereof so that moisture is not likely to enter the interlayer insulating film 68. The temperature for the heat treatment is set, for example, to 350° C. The time for the heat treatment is set, for example, to 2 minutes. In this heat treatment, the surface of the interlayer insulating film 68 is nitrided, and hence a silicon oxynitride film (not illustrated) is formed on the surface of the interlayer insulating film 68.

Subsequently, as illustrated in FIG. 2Q, the protective film 70 is formed, for example, by a sputtering or a CVD method. As the protective film 70, for example, an aluminum oxide film is formed. The thickness of the protective film 70 is set, for example, to approximately 20 to 50 nm.

Next, the interlayer insulating film 72 is formed, for example, by a plasma TEOS CVD method. As the interlayer insulating film 72, for example, a silicon oxide film is formed. The thickness of the interlayer insulating film 72 is set, for example, to approximately 300 nm.

Subsequently, as illustrated in FIG. 2R, the interlayer insulating film 72, the protective film 70, the interlayer insulating film 68, the protective film 66, and the protective film 64 are etched by using a photolithographic technique. Accordingly, the contact hole 74a reaching the lower electrode 48 and the contact hole 76b reaching the upper electrode 60 are formed.

Next, a heat treatment is performed in an oxygen atmosphere. This heat treatment is performed to supply oxygen to the capacitor dielectric film 54 and to improve the electrical properties of the capacitor 62. The temperature for the heat treatment is set, for example, to 400° C. to 600° C. The time for the heat treatment is set, for example, to 30 to 120 minutes.

In this embodiment, although the case in which the heat treatment is performed in an oxygen atmosphere is described by way of example, the heat treatment may also be performed in an ozone atmosphere. When the heat treatment is performed in an ozone atmosphere, oxygen is also supplied to the capacitor dielectric film 54, and the electrical properties of the capacitor 62 may also be improved.

Subsequently, as illustrated in FIG. 2S, the interlayer insulating film 72, the protective film 70, the interlayer insulating film 68, the protective film 66, and the interlayer insulating film 42 are etched by a photolithographic technique. Accordingly, the contact holes 76 reaching the conductive plugs 36 are formed.

Next, a heat treatment is performed in an inert gas atmosphere or in vacuum. This heat treatment is performed to discharge gases from the interlayer insulating films 72, 68, and 42 (degassing).

Next, by high frequency etching, a surface treatment is performed on inner wall surfaces of the contact holes 74a, 74b, and 76.

Next, the adhesive film 78 is formed on the entire surface by a sputtering method or the like. As the adhesive film 78, for example, a TiN film is formed. The thickness of the adhesive film 78 is set, for example, to approximately 50 to 150 nm. When a TiN film is formed as the adhesive film 78, Ti is used as a material for a target. As an atmosphere in a film formation chamber, a mixed gas atmosphere containing an Ar gas and a N₂ gas is used. The flow rate of an Ar gas is set, for example, to 50 sccm. The flow rate of a N₂ gas is set, for example, to 90 sccm. The temperature for the film formation is set, for example, to 200° C.

Next, a conductive film is formed on the entire surface by a CVD method or the like. As the conductive film, for example, a tungsten film is formed. The thickness of the conductive film is set, for example, to approximately 300 nm.

Next, the conductive film and the adhesive film 78 are polished, for example, by a CMP method until the surface of the interlayer insulating film 72 is exposed. Accordingly, the conductive plugs 80a to 80c are formed from the conductive film (see FIG. 2T).

Next, plasma cleaning is performed. As a gas used when the plasma cleaning is performed, for example, an Ar gas is used. Accordingly, native oxide films and the like present on the surfaces of the conductive plugs 80a to 80c are removed.

Next, for example, the TiN film 82, the AlCu alloy film 84, the Ti film 86, and the TiN film 88 are sequentially deposited to form a laminate film by a sputtering method or the like. The thickness of the TiN film 82 is set, for example, to 50 nm. The thickness of the AlCu alloy film 84 is set, for example, to 550 nm. The thickness of the Ti film 86 is set, for example, to 5 nm. The thickness of the TiN film 88 is set, for example, to 50 nm.

Next, the laminate film is etched by a photolithographic technique. Accordingly, the wires 90 are formed from the laminate film (see FIG. 2U).

Subsequently, furthermore, a plurality of layers each containing an interlayer insulating film (not illustrated), at least one conductive plug (not illustrated), at least one wire (not illustrated), and the like is formed. The number of wire layers (metal wire layers) thus formed is five.

As a result, the semiconductor device according to this embodiment is manufactured.

(Evaluation Result)

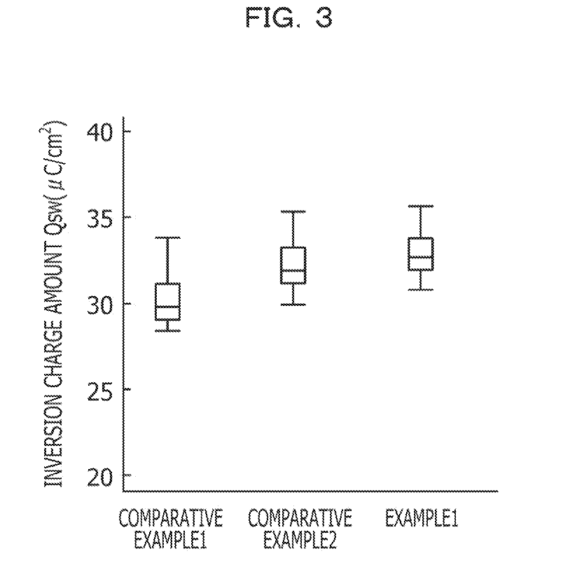

Next, evaluation results of the semiconductor device of this embodiment and the manufacturing method thereof will be described with reference to FIGS. 3 to 9.

In FIGS. 3 to 9, Example 1 is the case of this embodiment, that is, the case in which a PZT film added with La (PLZT film) is used as the ferroelectric film 50, and a PZT film added with La, Sr, and Ca (CSPLZT film) is used as the ferroelectric film 52.

Comparative Example 1 is the case in which a CSPLZT film is used as the ferroelectric film 50, and a CSPLZT film is used as the ferroelectric film 52.

Comparative Example 2 is the case in which a PLZT film is used as the ferroelectric film 50 and a PLZT film is used as the ferroelectric film 52.

In each of the cases of Example 1, Comparative Example 1, and Comparative Example 2, after the conductive film 44 was formed, a heat treatment was performed in an Ar gas atmosphere at 650° C. for 60 seconds by an RTA method. Subsequently, in each of the cases of Example 1, Comparative Example 1, and Comparative Example 2, the conductive film 44 thus processed was held in an oxygen atmosphere for 6 hours, so that a platinum oxide conductive film 46 having a thickness of 0.3 to 0.5 nm was formed on the conductive film 44. In addition, in each of the cases of Example 1, Comparative Example 1, and Comparative Example 2, the ferroelectric films 50 and 52 were each formed by a sputtering method. In each of the cases of Example 1, Comparative Example 1, and Comparative Example 2, the thicknesses of the ferroelectric films 50 and 50 were set to 90 nm and 15 nm, respectively.

In Example 1, the amount of La in the PLZT ferroelectric film 50 was set to 2.0 mole percent. In addition, in Example 1, the amounts of La, Sr, and Ca in the CSPLZT ferroelectric film 52 were set to 2.0, 2.0, and 5.0 mole percent, respectively.

In Comparative Example 1, the amounts of La, Sr, and Ca in the CSPLZT ferroelectric films 50 and 52 were set to 2.0, 2.0, and 5.0 mole percent, respectively.

In Comparative Example 2, the amounts of La in the PLZT ferroelectric films 50 and 52 were each set to 2.0 mole percent.

In each of the cases of Example 1, Comparative Example 1, and Comparative Example 2, as the conditions for the heat treatment performed immediately after the ferroelectric film 50 is formed, optimal conditions were selected in accordance with the respective materials.

In each of the cases of Example 1, Comparative Example 1, and Comparative Example 2, the temperature for forming the conductive film 56 was set to 300° C. The flow rate of an argon gas used when the conductive film 56 was formed was set to 140 sccm, and the flow rate of an oxygen gas was set to 60 sccm. In each of the cases of Example 1, Comparative Example 1, and Comparative Example 2, the thickness of the conductive film 56 was set to 25 nm.

In each of the cases of Example 1, Comparative Example 1, and Comparative Example 2, after the conductive film 56 was formed, the heat treatment was performed at 725° C. for 120 seconds. In each of the cases of Example 1, Comparative Example 1, and Comparative Example 2, the flow rate of an argon gas used in the heat treatment performed after the conductive film 56 was formed was set to 1,990 sccm, and the flow rate of an oxygen gas was set to 10 sccm.

In each of the cases of Example 1, Comparative Example 1, and Comparative Example 2, five metal wire layers were formed, and the electrical properties of the capacitor 62 of the semiconductor device thus formed were measured.

FIG. 3 is a graph (part 1) of measurement results of the inversion charge amounts of the capacitors. In the case illustrated in FIG. 3, the applied voltage used when the inversion charge amount was measured was set to 3 V, and the temperature at which the inversion charge amount was measured was set to room temperature. The size of the capacitor used for the measurement was set to 50 μm by 50 μm.

As illustrated in FIG. 3, in the case of Comparative Example 1, the inversion charge amount (Q_{SW}) of the capacitor is relatively small.

On the other hand, in Example 1, that is, in the case of this embodiment, a relatively large inversion charge amount is obtained.

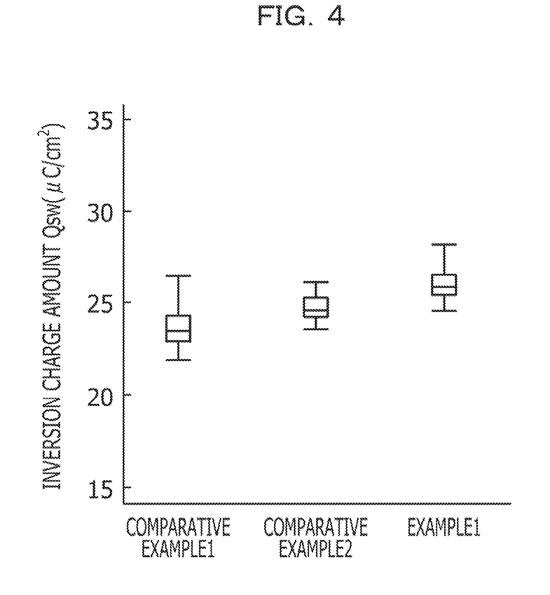

FIG. 4 is a graph (part 2) of measurement results of the inversion charge amounts of the capacitors. In the case illustrated in FIG. 4, the applied voltage used when the inversion charge amount was measured was set to 1.8 V, and the temperature at which the inversion charge amount was measured was set to room temperature. The size of the capacitor used for the measurement was set to 1.0 μm by 1.4 μm.

As illustrated in FIG. 4, in the cases of Comparative Examples 1 and 2, the inversion charge amount of the capacitor is relatively small.

On the other hand, in Example 1, that is, in the case of this embodiment, a relatively large inversion charge amount is obtained.

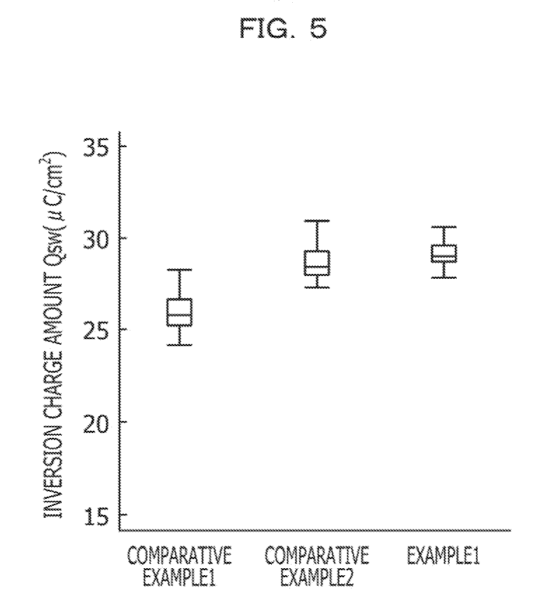

FIG. 5 is a graph (part 3) of measurement results of the inversion charge amounts of the capacitors. In the case illustrated in FIG. 5, the applied voltage used when the inversion charge amount was measured was set to 3.0 V, and the temperature at which the inversion charge amount was measured was set to room temperature. The size of the capacitor used for the measurement was set to 1.0 μm by 1.4 μm.

As illustrated in FIG. 5, in the case of Comparative Example 1, the inversion charge amount is relatively small.

On the other hand, in Example 1, that is, in the case of this embodiment, a relatively large inversion charge amount is obtained.

As illustrated in FIGS. 3 to 5, according to this embodiment, a capacitor 62 having a relatively large inversion charge amount Q_{SW} may be obtained.

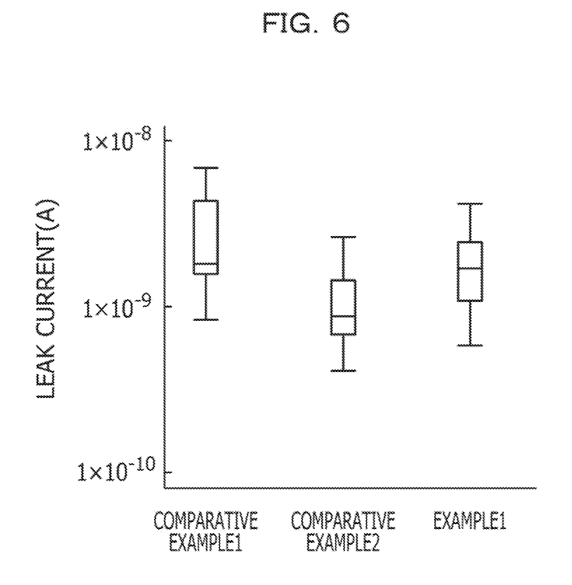

FIG. 6 is a graph of measurement results of the leak currents of the capacitors. In the case illustrated in FIG. 6, the applied voltage used when the leak current was measured was set to 5 V, and the temperature at which the leak current was measured was set to room temperature. The size of the capacitor used for the measurement was set to 50 μm by 50 μm.

As illustrated in FIG. 6, in the case of Comparative Example 1, the leak current is relatively large.

In the case of Comparative Example 1, an exemplary reason the leak current was increased is believed as follows. That is, when the ferroelectric films 50 and 52 are formed from CSPLZT, which is PZT added with La, Sr, and Ca, in the heat treatment to crystallize the ferroelectric films 50 and 52, voids are liable to be generated between crystalline grains of the ferroelectric films 50 and 52. When an iridium oxide conductive film 56 is formed on the capacitor dielectric film 54 which is formed from the ferroelectric films 50 and 52 as described above, and the heat treatment is then performed, Ir diffused from the conductive film 56 concentrates at the voids between the crystalline grains of the ferroelectric films 50 and 52, and as a result, leak paths are generated in the ferroelectric films 50 and 52. Accordingly, in Comparative Example 1, the leak current of the capacitor 62 becomes relatively large.

On the other hand, in Example 1, that is, in the case of this embodiment, the leak current is relatively small. However, the leak current in Example 1 is larger than that in Comparative Example 2.

In the case of Comparative Example 2, an exemplary reason the leak was relatively small is believed as follows. That is, when the ferroelectric films 50 and 52 are formed from PLZT, which is PZT added with La, in the heat treatment in which the ferroelectric films 50 and 52 are crystallized, voids are not likely to be generated between crystalline grains of the ferroelectric films 50 and 52. Hence, it is believed that in Comparative Example 2, leak paths are not likely to be generated in the ferroelectric films 50 and 52, and the leak current of the capacitor 62 becomes relatively small.

In Example 1, that is, in this embodiment, since CSPLZT is used as the ferroelectric film 52, the leak paths are generated therein, and since PLZT is used as the ferroelectric film 50, the leak paths are not likely to be generated therein. Accordingly, it is believed that the leak current in Example 1 is smaller than that in Comparative Example 1 and is larger than that in Comparative Example 2.

As described above, according to this embodiment, a capacitor 62 having a relatively small leak current may be obtained.

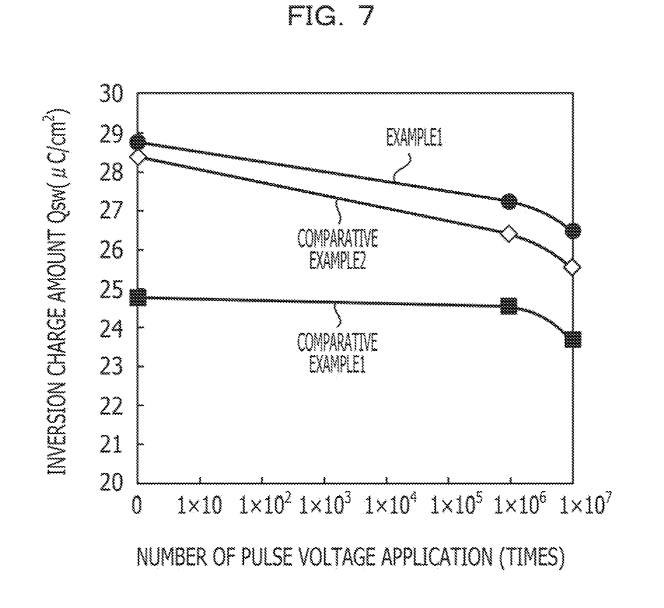

FIG. 7 is a graph of measurement results of the fatigue characteristics of the capacitors. In FIG. 7, indicates the results of Example 1, that is, the results of the semiconductor device according to this embodiment. In FIG. 7, ▪ indicates the results of Comparative Example 1. In FIG. 7, ⋄ indicates the results of Comparative Example 2. The horizontal axis in FIG. 7 indicates the number of pulse voltage application for applying a stress to the capacitor. The vertical axis in FIG. 7 indicates the inversion charge amount of the capacitor.

When the fatigue characteristics illustrated in FIG. 7 were measured, a pulse voltage of 7 V was repeatedly applied to the capacitor. The frequency of the pulse applied to the capacitor 62 was set to 1 MHz. When the inversion charge amount of the capacitor 62 was measured, the voltage applied thereto was set to 3 V. In addition, the inversion charge amount before the pulse voltage is applied to the capacitor, the inversion charge amount after the pulse voltage is applied to the capacitor 1×10⁶ times, and the inversion charge amount after the pulse voltage is applied to the capacitor 1×10⁷ times were respectively measured.

In the case of Comparative Example 1, the reduction rate of the inversion charge amount of the capacitor by applying the pulse voltage 1×10⁷ times was 4.7%.

In the case of Comparative Example 2, the reduction rate of the inversion charge amount of the capacitor by applying the pulse voltage 1×10⁷ times was 10.1%.

In the case of Example 1, the reduction rate of the inversion charge amount of the capacitor by applying the pulse voltage 1×10⁷ times was 7.7%.

From the above results, it is found that the reduction rate of the inversion charge amount of the capacitor 62 is lowest in Comparative Example 1. An exemplary reason the reduction rate of the inversion charge amount of the capacitor in Comparative Example 1 is low is believed that since CSPLZT is used as a material for the capacitor dielectric film 54, the interface between the capacitor dielectric film 54 and the upper electrode 60 is placed in good condition.

In Comparative Example 2, an exemplary reason the reduction rate of the inversion charge amount of the capacitor 62 is relatively high is believed that since PLZT is used as a material for the capacitor dielectric film 54, the interface between the capacitor dielectric film 54 and the upper electrode 60 is not always placed in good condition.

In Example 1, that is, in this embodiment, since CSPLZT is used as a material for the ferroelectric film 52, the interface between the capacitor dielectric film 54 and the upper electrode 60 is placed in relatively good condition, and hence the reduction in inversion charge amount of the capacitor is substantially suppressed. However, in Example 1, since the thickness of the ferroelectric film 52 is relatively small, the interface between the capacitor dielectric film 54 and the upper electrode 60 is not placed in good condition as compared to that in Comparative Example 1. Accordingly, it is believed that the reduction rate of the inversion charge amount of the capacitor 62 in Example 1 is higher than that in Comparative Example 1.

However, in the case of Comparative Example 1, although the reduction in inversion charge amount caused by the application of the pulse voltage is substantially suppressed, the inversion charge amount itself of the capacitor 62 is relatively small.

On the other hand, in Example 1, that is, in this embodiment, the inversion charge amount itself of the capacitor 62 is relatively large. In Example 1, since the inversion charge amount itself of the capacitor 62 is relatively large, and furthermore the reduction in inversion charge amount caused by the application of the pulse voltage is relatively low, an excellent capacitor may be obtained.

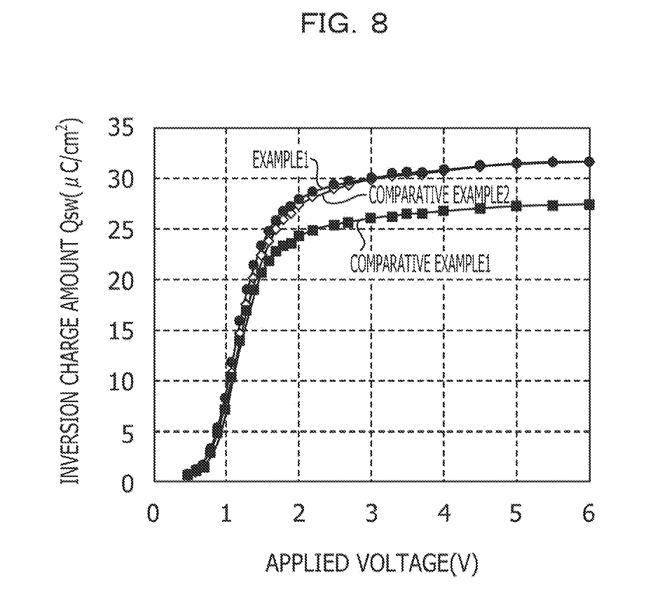

FIG. 8 is a graph illustrating the Q_{TV} properties of the capacitors, that is, the relationship between the applied voltage and the inversion charge amount. The horizontal axis in FIG. 8 indicates the voltage applied to the capacitor. The vertical axis in FIG. 8 indicates the inversion charge amount.

As illustrated in FIG. 8, in the case of Example 1, the Q_{TV} properties are excellent as compared to those of Comparative Examples 1 and 2. That is, compared to Comparative Examples 1 and 2, in Example 1, the inversion charge amount is large, and the rise of the Q_{TV} properties at the beginning is also fast. An exemplary reason the excellent Q_{TV} properties are obtained in Example 1 is believed that CSPLZT is used as a material for the ferroelectric film 52.

As described above, it is found that according to this embodiment, a capacitor having excellent electrical properties may be obtained.

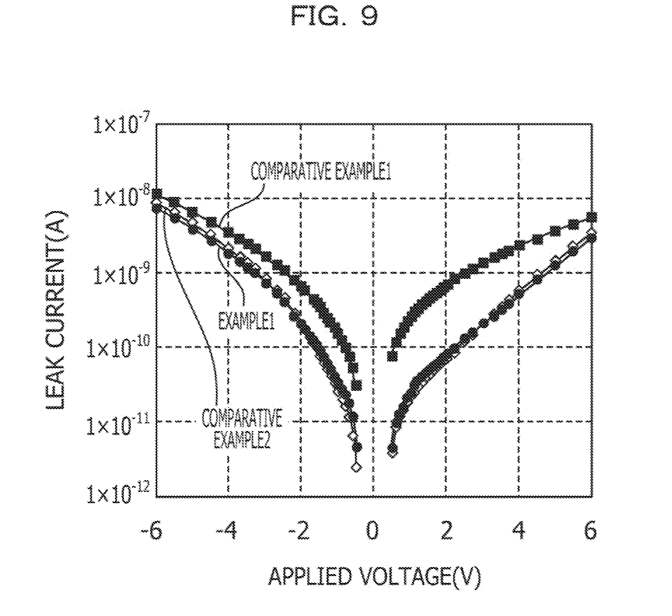

FIG. 9 is a graph illustrating the leak current properties of the capacitors. The horizontal axis in FIG. 9 indicates the voltage applied to the capacitor. The vertical axis in FIG. 9 indicates the leak current.

As illustrated in FIG. 9, in the case of Comparative Example 1, the leak current is relatively large.

On the other hand, in the case of Example 1, the leak current is relatively small.

An exemplary reason the leak current in Example 1 is smaller than that in Comparative Example 1 is believed that PLZT is used as a material for the ferroelectric film 50.

As described above, it is found that according to this embodiment, a capacitor having a small leak current may be obtained.

As described above, in this embodiment, the capacitor dielectric film 54 is formed from the PLZT ferroelectric film 50 and the CSPLZT ferroelectric film 52. According to this embodiment, since PLZT is used as the ferroelectric film 50, and since the PLZT ferroelectric film 50 is formed to have a relatively large thickness, the leak current of the capacitor 62 may be sufficiently reduced. Furthermore, according to this embodiment, since CSPLZT is used as the ferroelectric film 52, a capacitor in which degradation in hysteresis characteristics caused by imprint is substantially suppressed, the coercive electric field is low, and the fatigue characteristics are excellent may be obtained. Hence, according to this embodiment, a semiconductor device including a capacitor 62 having excellent properties may be provided.

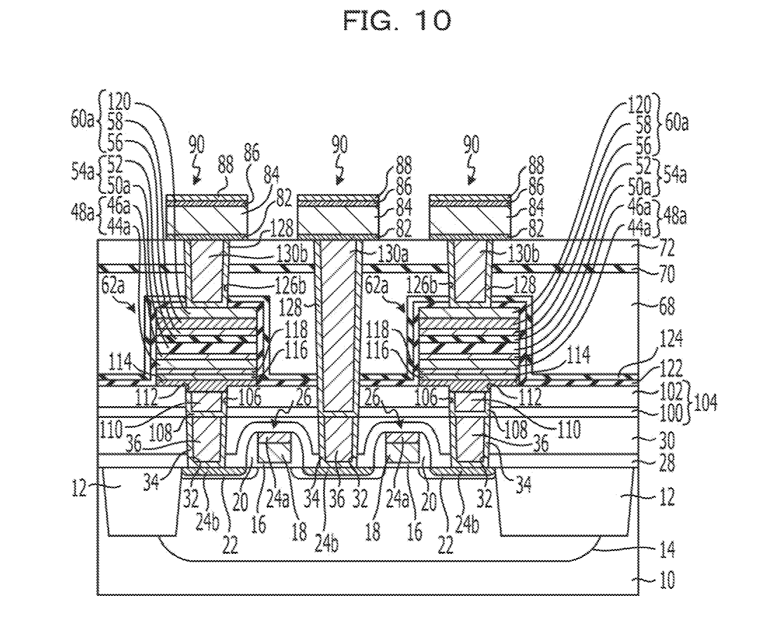

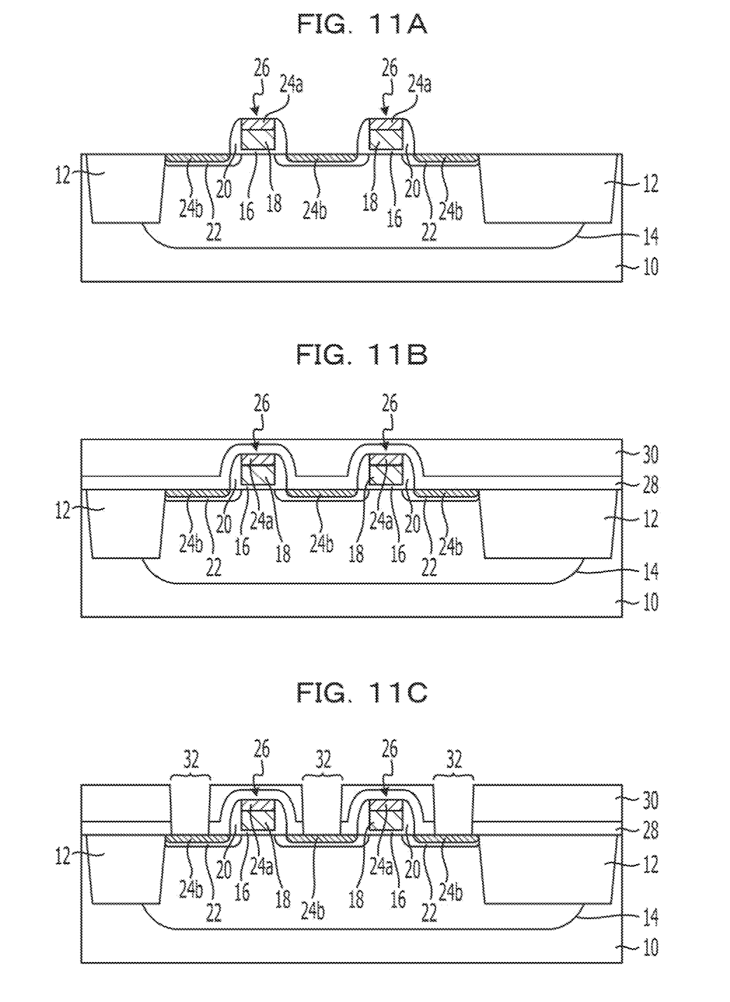

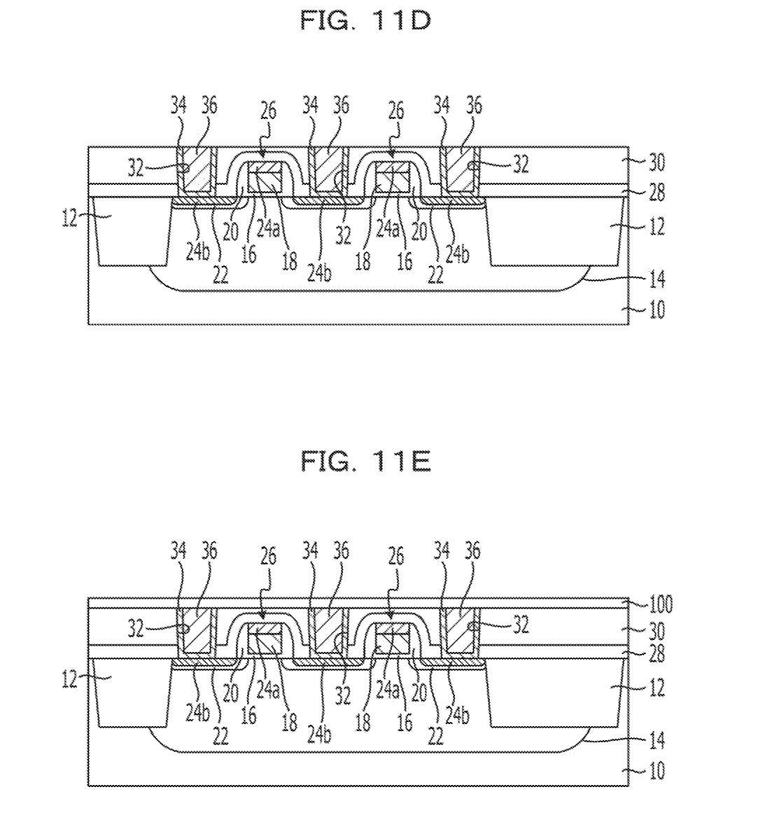

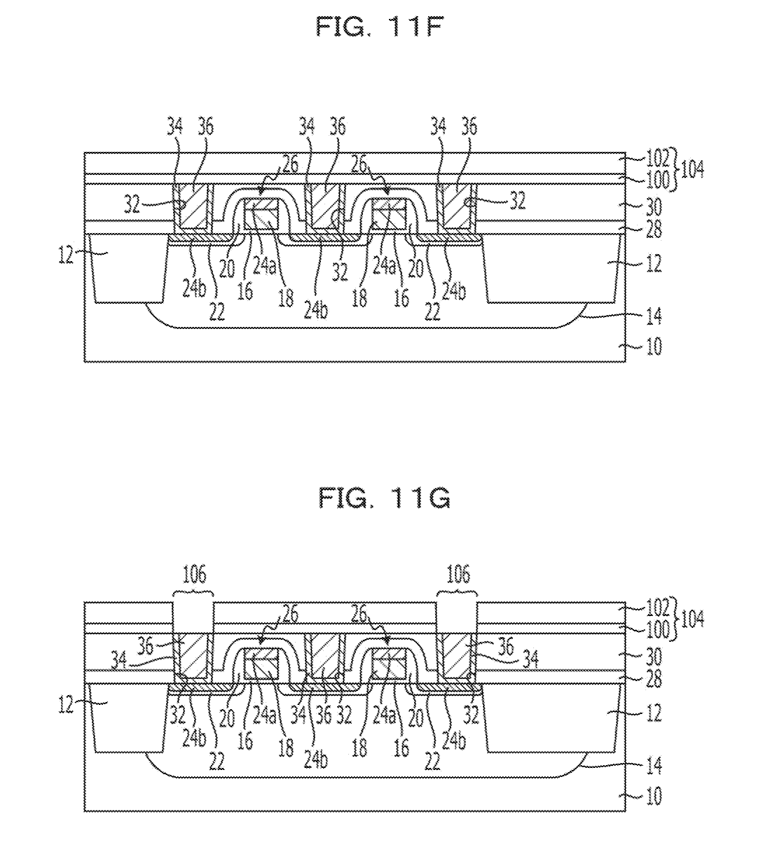

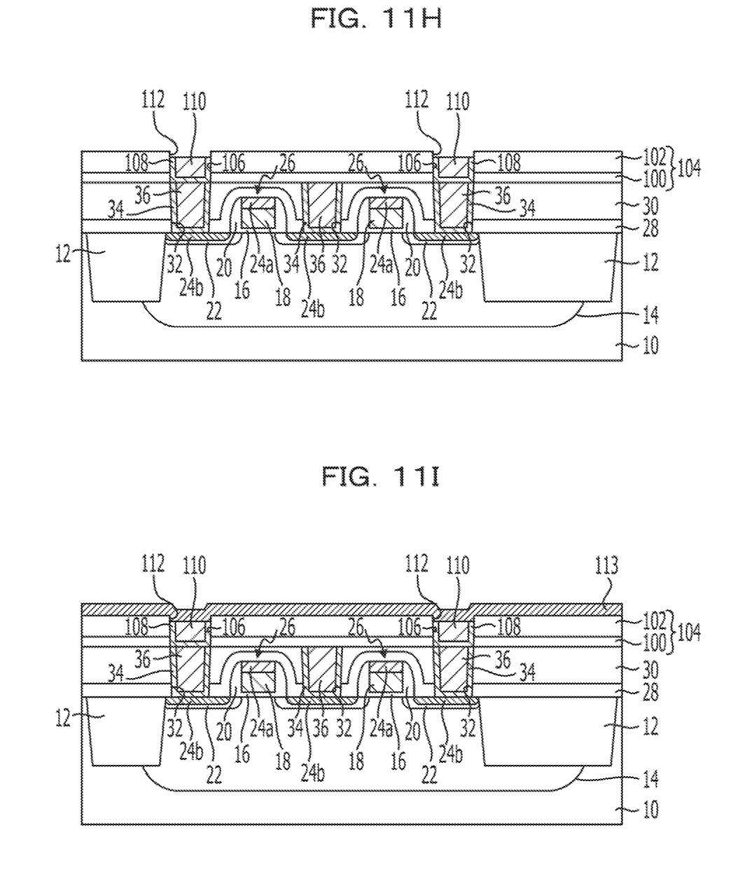

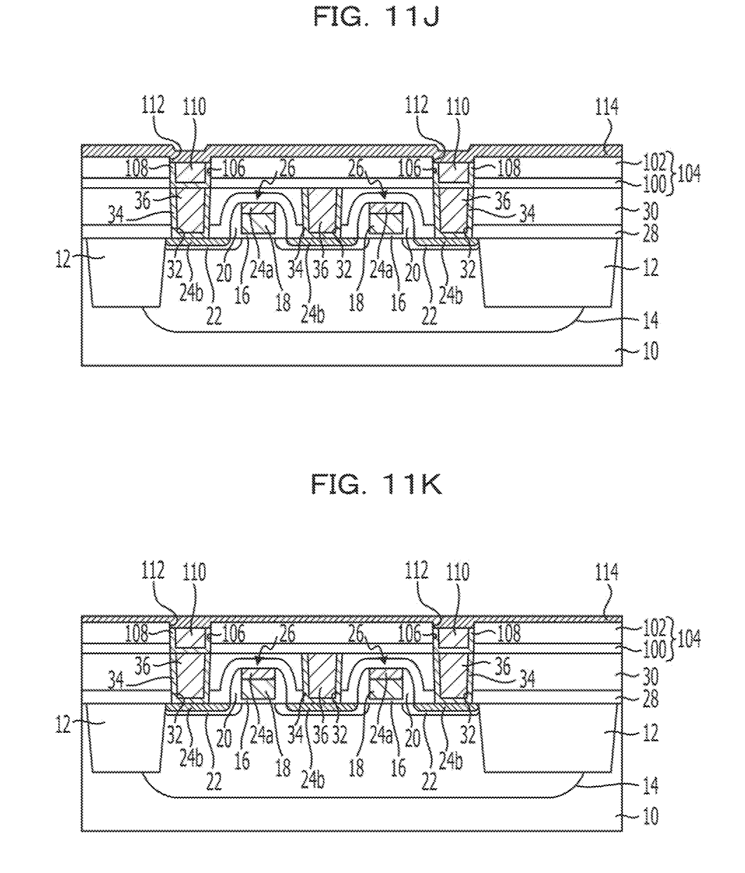

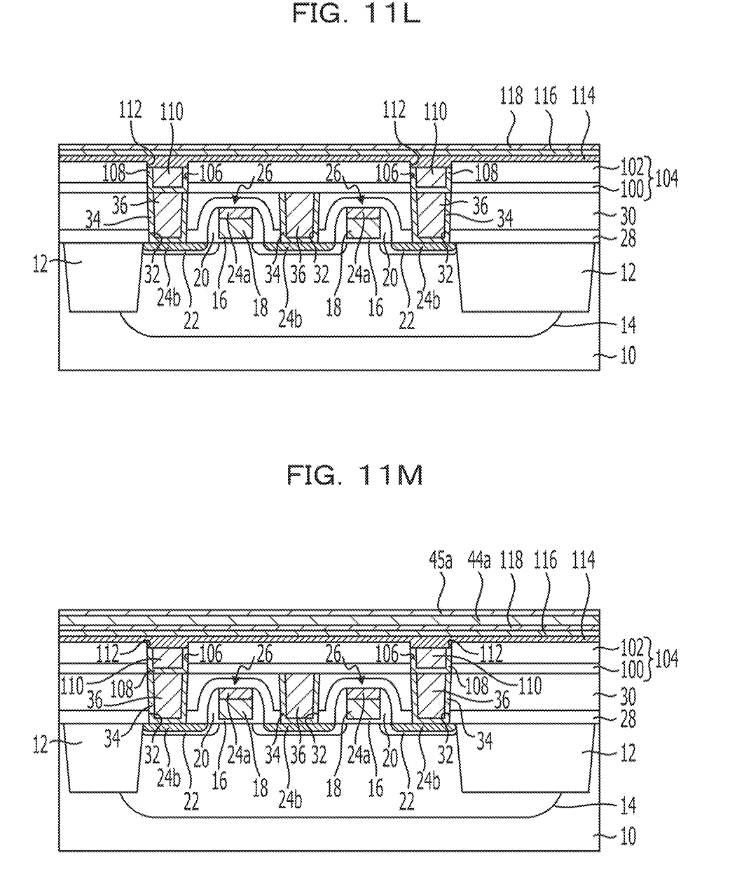

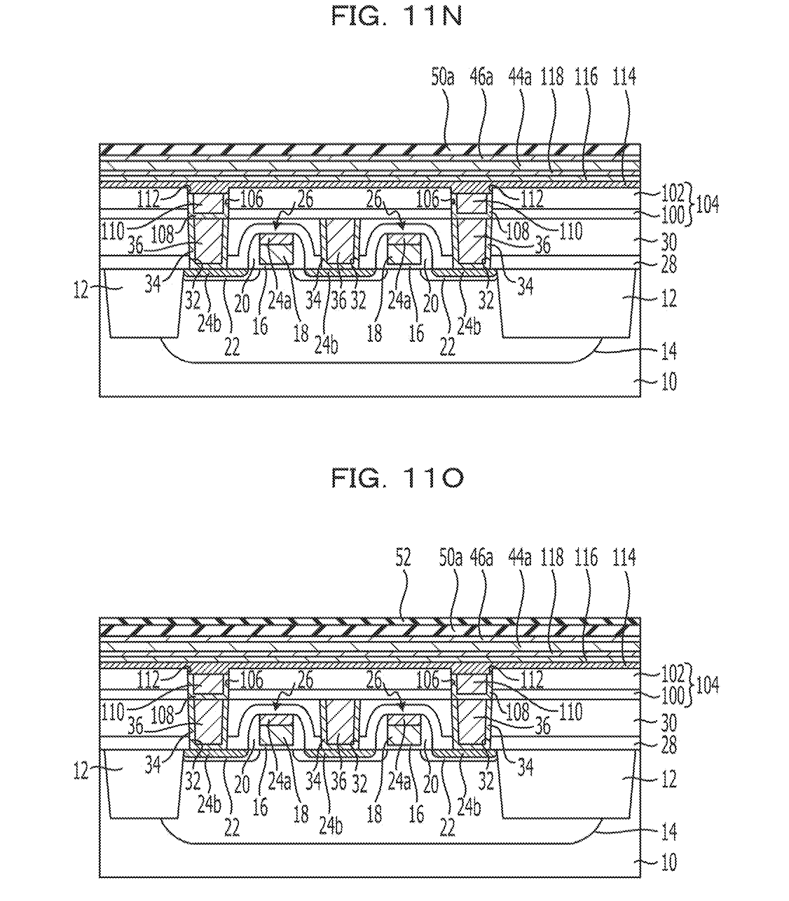

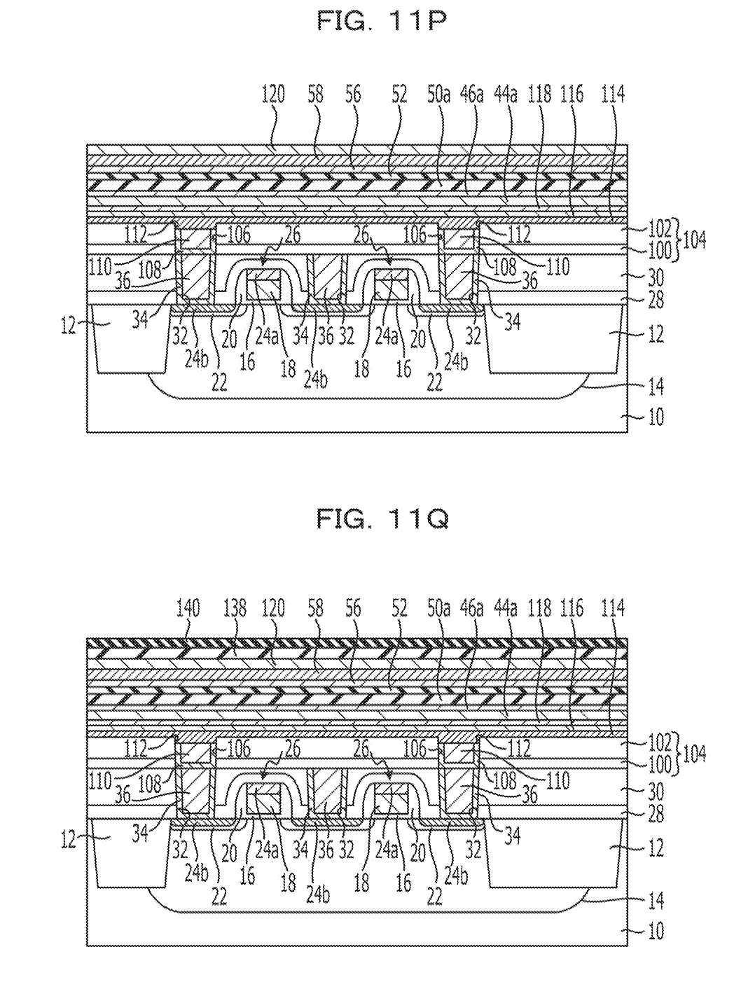

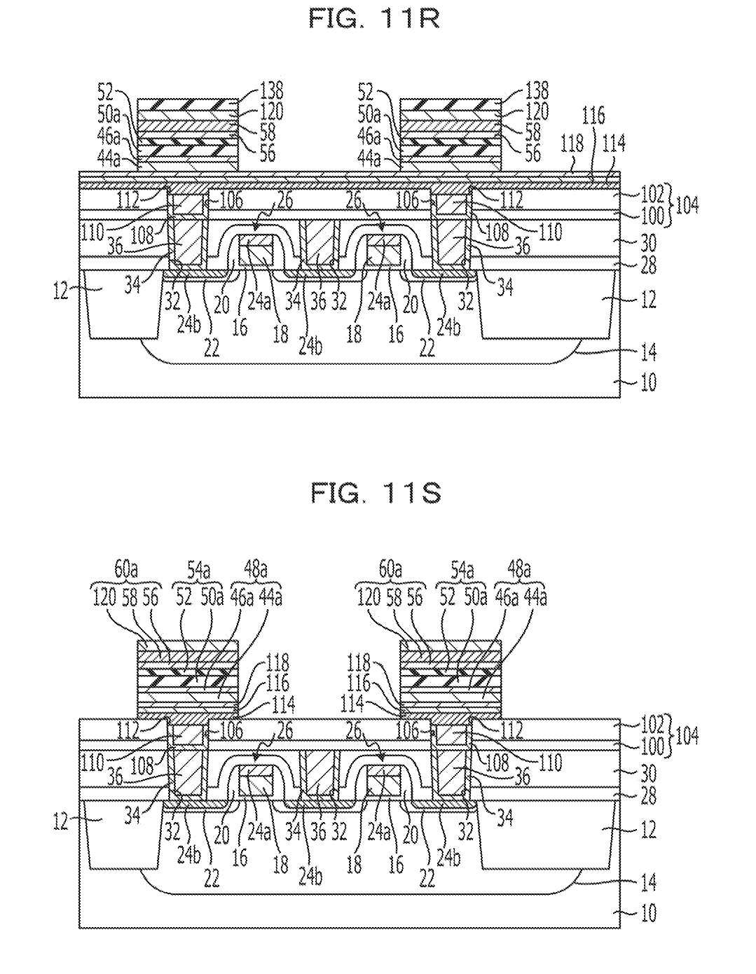

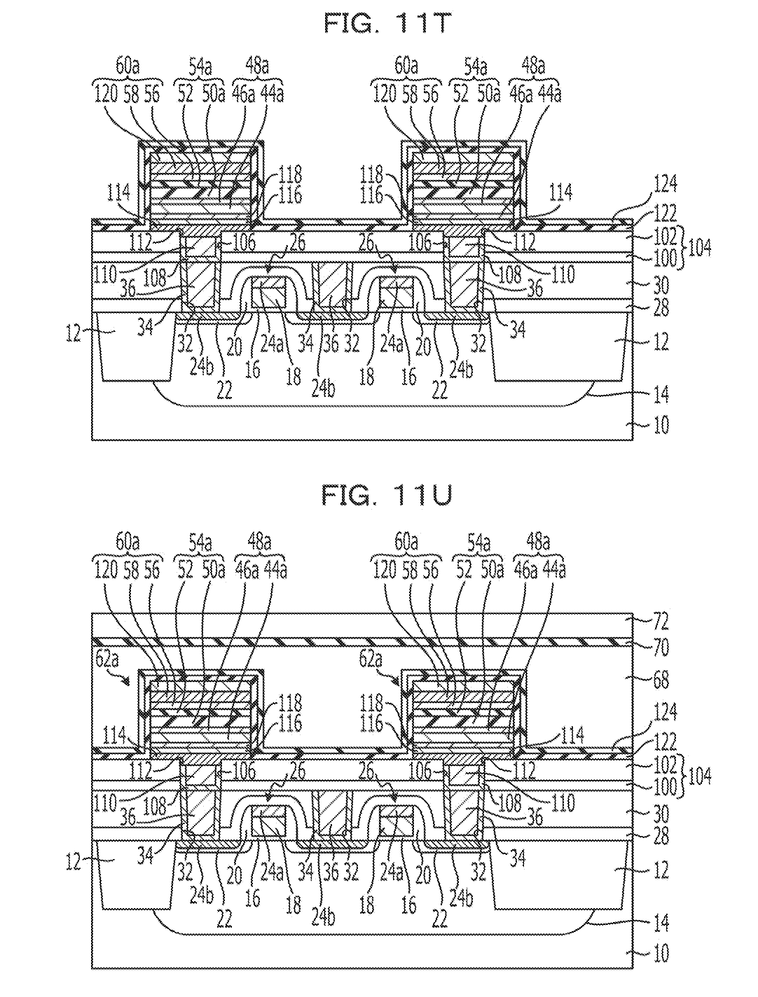

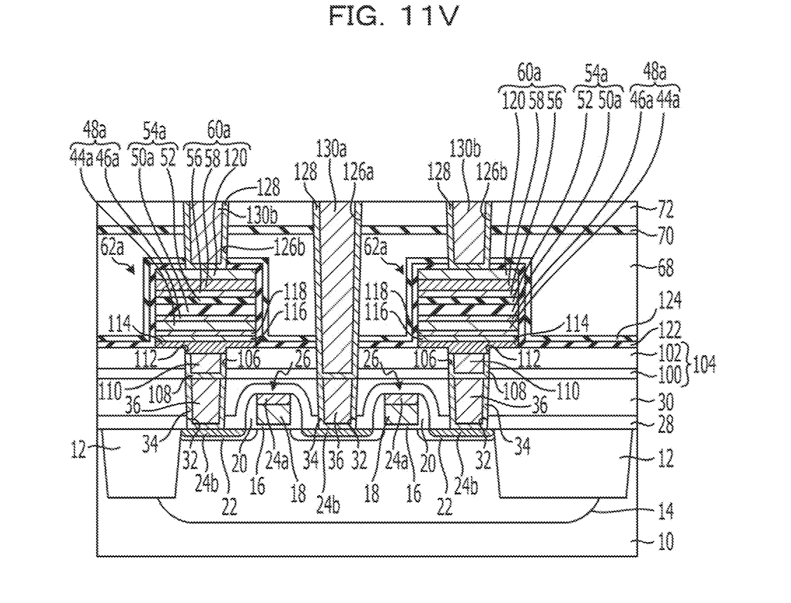

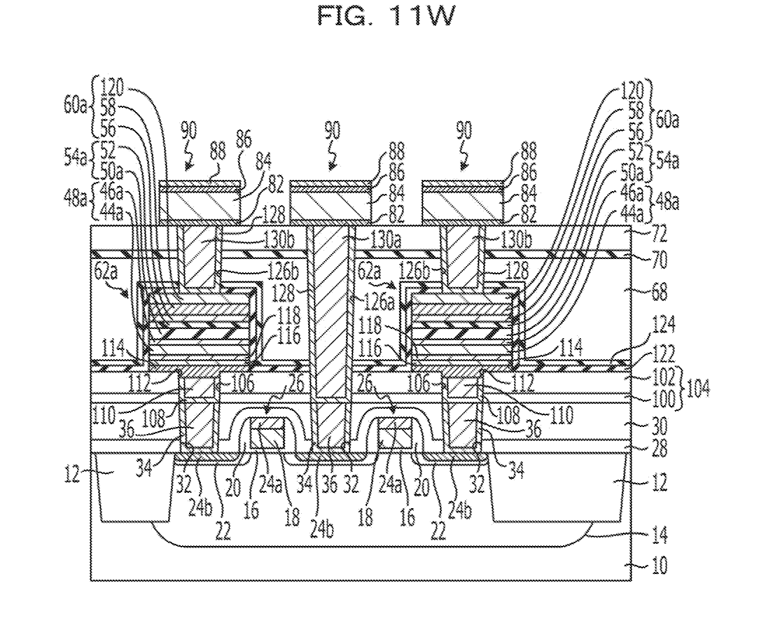

A semiconductor device according to a second embodiment and a manufacturing method thereof will be described with reference to FIGS. 10 to 11W. The same constituent elements as those of the semiconductor device according to the first embodiment and the manufacturing method thereof illustrated in FIGS. 1 to 9 will be designated by the same reference numerals as those in the first embodiment, and description thereof will be omitted or simplified.

First, the semiconductor device according to the second embodiment will be described with reference to FIG. 10. FIG. 10 is a cross-sectional view illustrating the semiconductor device according to this embodiment.

The semiconductor device of this embodiment is a device having a stacked memory cell structure.

As illustrated in FIG. 10, in a semiconductor substrate 10, an element isolation region 12 defining an element region is formed. As the semiconductor substrate 10, for example, an N-type or a P-type silicon substrate is used. In the semiconductor substrate 10 in which the element isolation region 12 is formed, for example, a P-type well 14 is formed.

A gate electrode (word line) 18 is formed on the semiconductor substrate 10 in which the well 14 is formed with a gate insulating film 16 interposed therebetween. Sidewall insulating films 20 are formed on sidewall portions of the gate electrode 18.

Source/drain diffusion layers 22 are formed at two sides of the gate electrode 18 provided with the sidewall insulating films 20.

Silicide layers 24a and 24b are formed on the gate electrode 18 and the source/drain diffusion layers 22, respectively. The silicide layers 24b on the source/drain diffusion layers 22 function as source/drain electrodes.

Accordingly, a transistor 26 including the gate electrode 18 and the source/drain diffusion layers 22 is formed.

An insulating film (oxidation preventing insulating film) 28 is formed on the semiconductor substrate 10 on which the transistor 26 is formed. The thickness of the insulating film 28 is set, for example, to 200 nm. As the insulating film 28, for example, a silicon oxynitride film is used.

An interlayer insulating film 30 is formed on the semiconductor substrate 10 on which the insulating film 28 is formed. The distance from the surface of the semiconductor substrate 10 to the surface of the interlayer insulating film 30 is set, for example, to 700 nm. As the interlayer insulating film 30, for example, a silicon oxide film is used. The surface of the interlayer insulating film 30 is planarized.

Contact holes 32 reaching the source/drain electrodes 24b are formed in the interlayer insulating film 30 and the insulating film 28.

An adhesive film 34 is formed in each contact hole 32. As the adhesive film 34, for example, a laminate film containing a Ti film and a TiN film, which are sequentially laminated to each other, is used. The thickness of the Ti film is set, for example, to 30 nm. The thickness of the TiN film is set, for example, to 20 nm.

A conductive plug 36 is filled in each contact hole 32 in which the adhesive film 34 is formed. As a material for the conductive plug 36, for example, tungsten (W) is used.

On the interlayer insulating film 30 in which the conductive plugs 36 are buried, for example, an oxidation preventing film 100 is formed. The thickness of the oxidation preventing film 100 is set, for example, to 130 nm. As the oxidation preventing film 100, for example, a silicon oxynitride film is used. The oxidation preventing film 100 is a film to substantially prevent the upper surfaces of the conductive plugs 36 being oxidized after the conductive plugs 36 are buried in the interlayer insulating film 30.

In this embodiment, although the case in which a silicon oxynitride film is used as the oxidation preventing film 100 is described by way of example, the oxidation preventing film 100 is not limited to a silicon oxynitride film. For example, as the oxidation preventing film 100, a silicon nitride film or an aluminum oxide film may also be formed.

On the oxidation preventing film 100, for example, a silicon oxide film 102 is formed. The thickness of the silicon oxide film 102 is set, for example, to 300 nm.

The oxidation preventing film 100 and the silicon oxide film 102 collectively form an interlayer insulating film 104.

A contact hole 106 reaching the conductive plug 36 is formed in the interlayer insulating film 104.

An adhesive film 108 is formed in the contact hole 106. As the adhesive film 108, for example, a laminate film containing a Ti film and a TiN film, which are sequentially laminated to each other, is used. The thickness of the Ti film is set, for example, to 30 nm. The thickness of the TiN film is set, for example, to 20 nm.

A conductive plug 110 is formed in the contact hole 106 in which the adhesive film 108 is formed. As a material for the conductive plug 110, for example, tungsten is used. The conductive plug 110 is buried in the interlayer insulating film 104, for example, by a CVD method, followed by a CMP method. Hence, when the conductive plug 110 is buried, for example, by a CVD method, followed by a CMP method, an upper portion of the conductive plug 110 is excessively polished, and the height of the upper surface of the conductive plug 110 may be located lower than the upper surface of the insulating film 104 in some cases. In this case, a recess 112 is formed at a position at which the conductive plug 110 is buried. The depth of the recess 112 is, for example, approximately 20 to 50 nm. When an adhesive film 116 which will be described later is formed on the interlayer insulating film 104 and the conductive plugs 110 on which the recesses 112 described above are formed, recesses are also formed in the surface of the adhesive film 116 due to the presence of the recesses 112. In addition, when an oxygen barrier film 118 is formed on the adhesive film 116 described above, recesses are also formed in the surface of the oxygen barrier film 118 due to the presence of the recesses described above. It is difficult to form a lower electrode 48a, a capacitor dielectric film 54a, and an upper electrode 60a, each having excellent orientation, on the oxygen barrier film 118 having the recesses described above. In this embodiment, as illustrated in FIG. 10, an underlayer 114 is formed on the conductive plugs 110 and the interlayer insulating film 104 so as to fill the recesses 112. The surface of the underlayer 114 described above is planarized by a CMP method. The thickness of the underlayer 114 is set, for example, to approximately 50 to 100 nm. In this embodiment, the thickness of the underlayer 114 is set to 50 nm.

The adhesive film 116 is formed on the underlayer 114. The adhesive film 116 described above functions to improve the crystallinity of the oxygen barrier film 118 which will be described later and also functions to improve the adhesion between the oxygen barrier film 118 and the interlayer insulating film 104. Since the adhesive film 116 is formed on the flat underlayer (planarized layer) 114, the surface of the adhesive film 116 is made flat. As the adhesive film 116, for example, a TiN film is formed. The thickness of the adhesive film 116 is set, for example, to approximately 20 nm.

In this embodiment, although the case in which a TiN film is used as the adhesive film 116 is described by way of example, the adhesive film 116 is not limited to a TiN film. A material capable of improving the crystallinity of the oxygen barrier film 118 and also of improving the adhesion between the oxygen barrier film 118 and the underlayer 114 may be appropriately used as a material for the adhesive film 116. For example, Ir or Pt may also be used as the material for the adhesive film 116.

The conductive oxygen barrier film (oxygen diffusion-preventing film) 118 is formed on the adhesive film 116. The thickness of oxygen barrier film 118 is set, for example, to 100 nm. As the oxygen barrier film 118, for example, a TiAlN film may be used. The oxygen barrier film 118 described above is a film to substantially prevent the upper surfaces of the conductive plugs 110 from being oxidized after the conductive plugs 110 are buried in the interlayer insulating film 104.

In this embodiment, although the case in which TiAlN is used as a material for the oxygen barrier film 118 is described by way of example, the material for the oxygen barrier film 118 is not limited to a TiAlN film. TiAlON, TaAlN, TaAlON, or the like may also be appropriately used as the material for the oxygen barrier film 118.

A conductive film 44a is formed on the oxygen barrier film 118. As the conductive film 44a, a noble metal film is used. In more particular, as the conductive film 44a, for example, an iridium (Ir) film is used. The thickness of the conductive film 44a is set, for example, to 100 nm.

In this embodiment, although the case in which an iridium film is used as the conductive film 44a is described by way of example, the conductive film 44a is not limited to an iridium film. As the conductive film 44a, for example, a ruthenium film may also be used. In addition, the conductive film 44a is not limited to a monolayer film and may be formed from a laminate film.

A conductive film 46a is formed on the conductive film 44a. The conductive film 46a is a noble metal film. A noble metal contained in the conductive film 46a is preferably the same element as that of a noble metal contained in the conductive film 44a. As described later, when the film formation is performed on the conductive film 44a, an amorphous noble metal oxide film 45a is formed (see FIG. 11M). The amorphous noble metal oxide film 45a is reduced into the noble metal film (conductive film) 46a, for example, by a heat treatment in a subsequent step. When a noble metal contained in the noble metal oxide film 45a is the same element as that of the noble metal contained in the conductive film 44a, the conductive film 46a and the conductive film 44a may not be discriminated from each other in some cases. In addition, since the conductive film 46a is a film obtained by reducing the amorphous noble metal oxide film 45a, the diameter of crystal grains of the conductive film 46a may be smaller than that of crystal grains of the conductive film 44a in some cases. For example, if an iridium oxide film (IrO_{X} film) is formed as the amorphous metal oxide film 45a, the iridium oxide film is reduced into an iridium film, for example, by a heat treatment in a subsequent step, and as a result, the conductive film 46a which is an iridium film is formed. The thickness of the conductive film 46a is set, for example, to approximately 25 nm.

Accordingly, the lower electrode 48a of a capacitor 62a is formed from the conductive films 44a and 46a.

A ferroelectric film 50a is formed on the lower electrode 48a. The ferroelectric film 50a is a film formed, for example, by an MOCVD method. As the ferroelectric film 50a, for example, a PLZT film, which is a PZT film added with La, is used. When being formed by an MOCVD method, the ferroelectric film 50a is deposited in a crystallized state.

The amount of La in the ferroelectric film 50a is set to 0.1 to 4.0 mole percent. In this embodiment, the amount of La in the ferroelectric film 50a is set, for example, to 2.0 mole percent.

The thickness of the ferroelectric film 50a is set, for example, to approximately 30 to 150 nm. More preferably, the thickness of the ferroelectric film 50a is set, for example, to approximately 50 to 120 nm. In this embodiment, the thickness of the ferroelectric film 50a is set, for example, to 90 nm.

In this embodiment, although the case in which the ferroelectric film 50a is formed by an MOCVD method is described by way of example, the ferroelectric film 50a is not limited to a film formed by an MOCVD method. For example, the ferroelectric film 50a may also be formed by a sputtering method.

A ferroelectric film 52 is formed on the ferroelectric film 50a. The ferroelectric film 52 is a film formed, for example, by a sputtering method. As the ferroelectric film 52, PZT added with La, Sr, and Ca, that is, CSPLZT, is used. The thickness of the ferroelectric film 52 is set, for example, to 5 to 30 nm. In this embodiment, the thickness of the ferroelectric film 52 is set to approximately 15 nm. The ferroelectric film 52 is crystallized, for example, by a heat treatment which will be described later.

The amount of La in the ferroelectric film 52 is set to 0.1 to 4.0 mole percent. In this embodiment, the amount of La in the ferroelectric film 52 is set, for example, to 2.0 mole percent.

In addition, the amount of Sr in the ferroelectric film 52 is set to 0.1 to 3.0 mole percent. In this embodiment, the amount of Sr in the ferroelectric film 52 is set, for example, to 2.0 mole percent.

In addition, the amount of Ca in the ferroelectric film 52 is set to 0.1 to 6.0 mole percent. In this embodiment, the amount of Ca in the ferroelectric film 52 is set, for example, to 5.0 mole percent.

In addition, the total amount of the impurities (La, Sr, and Ca) in the ferroelectric film 52 is set to 10.0 mole percent or less.

Accordingly, the capacitor dielectric film 54a is formed from the ferroelectric film 50a and the ferroelectric film 52.

A conductive film 56 is formed on the capacitor dielectric film 54a. The conductive film 56 is a conductive film crystallized when it is formed. As the conductive film 56, for example, an iridium oxide film is used. An oxygen composition ratio X of an iridium oxide film (IrO_{X} film) used as the conductive film 56 is set, for example, to satisfy 0<X<2. The thickness of the conductive film 56 is preferably set, for example, to approximately 10 to 70 nm. More preferably, the thickness of the conductive film 56 is set to approximately 20 to 50 nm. In this embodiment, the thickness of the conductive film 56 is set, for example, to approximately 50 nm.

A conductive film 58 is formed on the conductive film 56. The conductive film 58 is formed, for example, by a sputtering method. As the conductive film 58, for example, an iridium oxide film 58 is used. An oxygen composition ratio Y of an iridium oxide film (IrO_{Y} film) formed as the conductive film 58 is set, for example, to satisfy 0<Y≦2. The oxygen composition ratio Y of the iridium oxide film (IrO_{Y} film) formed as the conductive film 58 is preferably higher than the oxygen composition ratio X of the iridium oxide film (IrO_{X} film) formed as the conductive film 56. The thickness of the conductive film 58 is preferably set, for example, to approximately 100 to 300 nm. In this embodiment, the thickness of the conductive film 58 is set, for example, to approximately 200 nm.

A hydrogen barrier film 120 is formed on the conductive film 58. As the hydrogen barrier film 120, for example, an iridium film is used. The hydrogen barrier film 120 functions to substantially prevent the capacitor dielectric film 54a from being reduced by hydrogen.

In this embodiment, although the case in which an iridium film is used as the hydrogen barrier film 120 is described by way of example, the hydrogen barrier film 120 is not limited to an iridium film. For example, a Pt film or an SrRuO₃ film may also be used as the hydrogen barrier film 120.

The upper electrode 60a is formed from the conductive film 56, the conductive film 58, and the hydrogen barrier film 120.

Accordingly, the capacitor 62a having the lower electrode 48a, the capacitor dielectric film 54a, and the upper electrode 60a is formed.

On the interlayer insulating film 104 on which the capacitor 62a, a protective film 122 is formed is formed so as to cover the capacitor 62a. The thickness of the protective film 122 is set, for example, to approximately 20 nm. As the protective film 122, for example, an aluminum oxide film is used. The protective film 122 described above is a film to substantially prevent the capacitor dielectric film 54a from being reduced by hydrogen.

A protective film 124 is further formed on the protective film 122. The thickness of the protective film 124 is set, for example, to approximately 38 nm. As the protective film 124, for example, an aluminum oxide film is used as in the case of the protective film 122. The protective film 124 described above is a film to substantially prevent the capacitor dielectric film 54a from being reduced by hydrogen in cooperation with the protective film 122.

An interlayer insulating film 68 is formed on the protective film 124. The thickness of the interlayer insulating film 68 is set, for example, to 1,500 nm. As the interlayer insulating film 68, for example, a silicon oxide film is used. The surface of the interlayer insulating film 68 is planarized.

A protective film 70 is formed on the interlayer insulating film 68. The thickness of the protective film 70 is set, for example, to 20 to 100 nm. As a material for the protective film 70, as in the case of the protective films 122 and 124, for example, aluminum oxide is used. As in the case of the protective films 122 and 124, the protective film 70 described above is a film to substantially prevent the capacitor dielectric film 54a from being reduced by hydrogen. Since being formed on the planarized interlayer insulating film 68, the protective film 70 is formed flat.

An interlayer insulating film 72 is formed on the protective film 70. The thickness of the interlayer insulating film 72 is set, for example, to approximately 800 to 1,000 nm. As the interlayer insulating film 72, for example, a silicon oxide film is formed. The surface of the interlayer insulating film 72 is planarized.

A contact hole 126a reaching the conductive plug 36 is formed in the interlayer insulating film 72, the protective films 70, the interlayer insulating film 68, the protective film 124, the protective film 122, and the interlayer insulating film 104.

A contact hole 126b reaching the upper electrode 60a is formed in the interlayer insulating film 70, the protective film 70, the interlayer insulating film 68, the protective film 124, and the protective film 122.

Adhesive films 128 are formed in the contact holes 126a and 126b. The adhesive film 128 is formed, for example, of a laminate film containing a Ti film and a TiN film. The thickness of the Ti film is set, for example, to 30 nm. The thickness of the TiN film is set, for example, to 20 nm.

Conductive plugs 130a and 130b are formed in the contact holes 126a and 126b, respectively, provided with the adhesive films 128. As a material for the conductive plugs 130a and 130b, for example, tungsten is used.

Wires 90 are formed on the interlayer insulating film 72 in which the conductive plugs 130a and 130b are buried. The wire 90 is formed, for example, by sequentially laminating a TiN film 82, an AlCu alloy film 84, a Ti film 86, and a TiN film 88.

A plurality of layers each containing an interlayer insulating film (not illustrated), at least one conductive plug (not illustrated), at least one wire (not illustrated), and the like is further formed on the interlayer insulating film 72 on which the wires 90 are formed.

As a result, the semiconductor device according to this embodiment is formed.

As in this embodiment, the memory cell structure may also be a stacked type.

(Method for Manufacturing Semiconductor Device)

Next, the method for manufacturing the semiconductor device according to this embodiment will be described with reference to FIGS. 11A to 11W. FIGS. 11A to 11W are cross-sectional views illustrating the method for manufacturing the semiconductor device according to this embodiment.

First, as illustrated in FIG. 11A, the element isolation region 12 defining an element region is formed in the semiconductor substrate 10 by an STI method or the like. As the semiconductor substrate 10, for example, an N-type or a P-type silicon substrate is used.

Next, a dopant is implanted by an ion implantation method, so that the well 14 is formed. As the dopant, for example, a P-type dopant is used. As the P-type dopant, for example, boron is used. When a P-type dopant is used as the dopant, the well 14 is formed to have a P-type conductivity.

Next, the gate insulating film 16 is formed on the element region by a thermal oxidation method or the like. The thickness of the gate insulating film 16 is set, for example, to approximately 6 to 7 nm.

Next, a polysilicon film 18 is formed, for example, by a CVD method. The thickness of the polysilicon film 18 is set, for example, to approximately 200 nm. The polysilicon film 18 is used as a gate electrode (word line).

Next, by a photolithographic technique, the polysilicon film 18 is patterned. Accordingly, the gate electrode (word line) 18 is formed from the polysilicon film.

Next, a dopant is implanted, for example, by an ion implantation method in the semiconductor substrate 10 at two sides of the gate electrode 18 using the gate electrode 18 as a mask. As the dopant, for example, an N-type dopant is used. As the N-type dopant, for example, phosphorus is used. Accordingly, extension regions (not illustrated) forming shallow regions of extension source/drain are formed.

Next, an insulating film is formed on the entire surface by a CVD method or the like. As the insulating film, for example, a silicon oxide film is formed. The thickness of the insulating film is set, for example, to approximately 300 nm.

Next, anisotropic etching is performed on the insulating film. Accordingly, the sidewall insulating films 20 are formed on the sidewall portions of the gate electrode 18.

Next, a dopant is implanted, for example, by an ion implantation method in the semiconductor substrate 10 at the two sides of the gate electrode 18 using the gate electrode 18 provided with the sidewall insulating films 20 as a mask. As the dopant, for example, an N-type dopant is used. As the N-type dopant, for example, arsenic is used. Accordingly, impurity diffusion layers (not illustrated) forming deep regions of the extension source/drain are formed. The source/drain diffusion layers 22 are formed form the extension regions and the deep impurity diffusion layers.

Next, a high melting point metal film (not illustrated) is formed on the entire surface by a sputtering method or the like. As the high melting point metal film, for example, a cobalt film is formed.

Next, by performing a heat treatment, a surface layer portion of the semiconductor substrate 10 and the high melting point metal film are allowed to react with each other, and an upper portion of the gate electrode 18 and the high melting point metal film are also allowed to react with each other.

Next, an unreacted high melting point metal film is removed, for example, by wet etching.

Accordingly, for example, the source/drain electrodes 24b of cobalt silicide are formed on the source/drain diffusion layers 22. In addition, for example, the silicide layer 24a of cobalt silicide is formed on the upper portion of the gate electrode 18.

As a result, the transistor 26 having the gate electrode 18 and the source/drain diffusion layers 22 is formed.

Next, the insulating film (oxidation preventing film) 28 is formed on the entire surface by a plasma CVD method or the like. As the insulating film 28, for example, a silicon oxynitride film is formed. The thickness of the insulating film 28 is set, for example, to 200 nm.

Next, the interlayer insulating film 30 is formed on the entire surface by a plasma TEOS CVD method or the like. As the interlayer insulating film 30, for example, a silicon oxide film is formed. The thickness of the interlayer insulating film 30 is set, for example, to 1 μm.

Next, the surface of the interlayer insulating film 30 is planarized, for example, by a CMP method. Accordingly, the distance from the surface of the semiconductor substrate 10 to the surface of the interlayer insulating film 30 is, for example, approximately 700 nm (see FIG. 11B).

Subsequently, as illustrated in FIG. 11C, the contact holes 32 reaching the source/drain electrodes 24b are formed by a photolithographic technique. The diameter of the contact hole 32 is set, for example, to 0.25 μm.

Next, a Ti film is formed on the entire surface by a sputtering method or the like. The thickness of the Ti film is set, for example, to approximately 30 nm.

Next, a TiN film is formed on the entire surface by a sputtering method or the like. The thickness of the TiN film is set, for example, to approximately 20 nm.

Accordingly, the adhesive film 34 is formed from the Ti film and the TiN film.

Next, a conductive film 36 is formed on the entire surface by a CVD method or the like. As the conductive film 36, for example, a tungsten film is formed. The thickness of the conductive film 36 is set, for example, to approximately 300 nm.

Next, the conductive film 36 and the adhesive film 34 are polished, for example, by a CMP method until the surface of the interlayer insulating film 30 is exposed. Accordingly, the conductive plug 36 of tungsten or the like is filled in the contact hole 32 (see FIG. 11D).

Next, as illustrated in FIG. 11E, a silicon oxynitride film 100 is formed on the entire surface by a plasma CVD method or the like. The thickness of the silicon oxynitride film 100 is set, for example, to 130 nm.

In this embodiment, although the silicon oxynitride film 100 is formed, instead of the silicon oxynitride film 100, a silicon nitride film, an aluminum oxide film, or the like may also be formed.

Subsequently, as illustrated in FIG. 11F, the silicon oxide film 102 is formed on the entire surface by a plasma TEOS CVD method or the like. The thickness of the silicon oxide film 102 is set, for example, to 300 nm.

The silicon oxynitride film 100 and the silicon oxide film 102 collectively form the interlayer insulating film 104.

Next, as illustrated in FIG. 11G, the contact holes 106 reaching the conductive plugs 36 are formed in the interlayer insulating film 104.

Next, a Ti film is formed on the entire surface by a sputtering method or the like. The thickness of the Ti film is set, for example, to approximately 30 nm.

Next, a TiN film is formed on the entire surface by a sputtering method or the like. The thickness of the TiN film is set, for example, to approximately 20 nm.

Accordingly, the adhesive film 108 is formed from the Ti film and the TiN film.

Next, a conductive film 110 is formed on the entire surface by a CVD method or the like. As the conductive film 110, for example, a tungsten film is formed. The thickness of the conductive film 110 is set, for example, to approximately 300 nm.

Next, the conductive film 110 and the adhesive film 108 are polished by a CMP method or the like until the surface of the interlayer insulating film 104 is exposed. When the conductive film 110 and the adhesive film 108 are polished, an abrasive powder is selected so that a polishing rate of the conductive film 110 and the adhesive film 108 is faster than that of the interlayer insulating film 104. As the abrasive powder described above, for example, an abrasive powder (product name: SSW2000) manufactured by Cabot Microelectronics Corp. is used. When the conductive film 110 and the adhesive film 108 are polished by the abrasive powder as described above, the conductive film 110 and the adhesive film 108 are excessively polished, and as a result, as illustrated in FIG. 11H, the upper surface of the conductive plug 110 may be located lower than that of the interlayer insulating film 104 in some cases. In this case, the recess 112 is formed at a position at which the conductive plug 110 is buried. The depth of the recess 112 thus formed is, for example, approximately 20 to 50 nm. Accordingly, the conductive plug 110 of tungsten or the like is filled in the contact hole 106.

Next, the surface of the interlayer insulating film 104 is exposed to a plasma atmosphere generated using an NH₃ gas or the like, so that the surface thereof is treated (plasma treatment). In this embodiment, an exemplary reason the surface of the interlayer insulating film 104 is exposed to a plasma atmosphere generated by using an NH₃ gas is that an NH group is bonded to oxygen atoms on the surface of the interlayer insulating film 104 so as to substantially prevent Ti atoms from being trapped by the oxygen atoms on the surface of the interlayer insulating film 104 when a Ti film 113 is formed on the interlayer insulating film 104 in a subsequent step.

The plasma treatment is performed under the following conditions. As a plasma processing apparatus, a parallel plate type plasma processing apparatus is used. A counter electrode is placed, for example, at a position approximately 9 mm (350 mils) apart from the semiconductor substrate 10. The pressure inside a chamber in which plasma processing is performed is set, for example, to approximately 266 Pa (2 Torr). The substrate temperature is set, for example, to 400° C. The flow rate of an NH₃ gas introduced into the chamber is set, for example, to 350 sccm. A high frequency electrical power applied to the semiconductor substrate 10 is set, for example, to 100 W at 13.56 MHz. A high frequency electrical power applied to the counter electrode is set, for example, to 55 W at 350 kHz. The time for applying a high frequency electrical power is set, for example, to 60 seconds.

Next, as illustrated in FIG. 11I, the Ti film 113 is formed on the entire surface by a sputtering method or the like. The thickness of the Ti film 113 is set, for example, to approximately 100 to 300 nm. In this embodiment, the thickness of the Ti film 113 is set to approximately 100 nm. Since the surface of the interlayer insulating film 104 is treated as described above, Ti atoms deposited on the interlayer insulating film 104 is freely movable on the surface thereof without being trapped by oxygen atoms. Hence, an excellent Ti film 113 which is self-oriented in the (002) direction is formed on the interlayer insulating film 104.

The Ti film 113 is formed, for example, under the following conditions. That is, the distance between the semiconductor substrate 10 and a target is set, for example, to 60 mm. The pressure inside a film formation chamber is set to 0.15 Pa. As an atmosphere in the film formation chamber, for example, an Ar atmosphere is used. The substrate temperature is set, for example, to 20° C. A DC power to be supplied is set, for example, to 2.6 kW. The time for supplying a DC power is set, for example, to 5 seconds.

Next, a heat treatment is performed in a nitrogen atmosphere by an RTA method or the like. The temperature for the heat treatment is set, for example, to 650° C. The time for the heat treatment is set, for example, to 60 seconds. By this heat treatment, the Ti film 113 is turned into a TiN film 114 (see FIG. 11J). Accordingly, the underlayer 114 which is a (111) oriented TiN film is obtained.

In this embodiment, although the case in which a TiN film is used as the underlayer 114 is described by way of example, the underlayer 114 is not limited to a TiN film. For example, a tungsten film, a silicon film, or a cupper film may also be formed as the underlayer 114.

Next, the surface of the underlayer 114 is polished by a CMP method. As an abrasive powder, for example, an abrasive powder (product name: SSW2000) manufactured by Cabot Microelectronics Corp. is used. Accordingly, a planarized layer 114, the surface of which is planarized, is formed (see FIG. 11K). An exemplary reason the surface of the underlayer 114 is planarized in this embodiment is that on the underlayer 114 thus planarized, the lower electrode 48a, the capacitor dielectric film 54a, and the upper electrode 60a, each of which has excellent orientation, may be formed. The thickness of the underlayer 114 thus polished is set, for example, to approximately 50 to 100 nm. In this embodiment, the thickness of the underlayer 114 thus polished is set to approximately 50 nm.

Next, the surface of the underlayer (planarized layer) 114 is exposed to a plasma atmosphere generated using an NH₃ gas or the like, so that the surface of the underlayer 114 is treated (plasma treatment).

In this embodiment, an exemplary reason the underlayer 114 is processed by a plasma treatment is as follows. That is, at the stage at which the underlayer 114 is planarized by a CMP method, the crystal of a surface layer portion of the underlayer 114 is distorted by the polishing. The lower electrode 48a having excellent crystallinity may not be formed on the underlayer 114 in which the crystal of the surface layer portion is distorted, and hence the capacitor dielectric film 54a having excellent crystallinity may not be formed. On the other hand, when the plasma treatment is performed on the underlayer 114, the distortion of the crystal of the surface layer portion thereof is substantially eliminated, and hence the film provided on the underlayer 114 is not adversely influenced. Accordingly, the lower electrode 48a and the capacitor dielectric film 54a, each of which has excellent crystallinity, may be formed on the underlayer 114. By the exemplary reason described above, in this embodiment, the plasma treatment is performed on the underlayer 114.

Next, a Ti film is formed on the entire surface by a sputtering method or the like. The thickness of the Ti film is set, for example, to approximately 20 nm. Since being formed on the underlayer 114 processed by the plasma treatment, the Ti film is deposited so as to have excellent quality.

Next, a heat treatment is performed in a nitrogen atmosphere by an RTA method or the like. The temperature for the heat treatment is set, for example, to 650° C. The time for the heat treatment is set, for example, to 60 seconds. By this heat treatment, the Ti film described above is turned into a TiN film. Accordingly, the adhesive film 116 is formed from a (111) oriented TiN film (see FIG. 11L). The adhesive film 116 described above is a film to improve the crystallinity of the oxygen barrier film 118 formed in a subsequent step and also to improve the adhesion between the oxygen barrier film 118 and the underlayer 114.

In this embodiment, although the case in which the adhesive film 116 is formed from a TiN film is described by way of example, the adhesive film 116 is not limited to a TiN film. A material capable of improving the crystallinity of the oxygen barrier film 118 and also of improving the adhesion between the oxygen barrier film 118 and the underlayer 114 may be appropriately used as a material for the adhesive film 116. For example, an Ir film or a Pt film may also be used for forming the adhesive film 116.

Next, the oxygen barrier film (oxygen diffusion-preventing film) 118 is formed on the entire surface by a reactive sputtering method or the like. The thickness of the oxygen barrier film 118 is set, for example, to approximately 100 nm. As the oxygen barrier film 118, for example, a TiAlN film is formed. The oxygen barrier film 118 is a film to substantially prevent the upper surfaces of the conductive plugs 110 being oxidized after the conductive plugs 110 are buried in the interlayer insulating film 104.

The oxygen barrier film 118 is formed, for example, under the following conditions. That is, as a target, a target formed from a TiAl alloy is used. As an atmosphere in a chamber, a mixed gas atmosphere containing an Ar gas and a nitrogen gas is used. The flow rate of an Ar gas is set, for example, to 40 sccm. The flow rate of a nitrogen gas is set, for example, to 10 sccm. The pressure inside the chamber is set, for example, to 253.3 Pa. The substrate temperature is set, for example, to 400° C. A sputtering power is set, for example, to 1 kW.

In this embodiment, although the case in which TiAlN is used as a material for the oxygen barrier film 118 is described by way of example, the material for the oxygen barrier film 118 is not limited to TiAlN. A conductive substance capable of substantially preventing the diffusion of oxygen may be appropriately used as the material for the oxygen barrier film 118. For example, TiAlON, TaAlN, or TaAlON may also be used as the material for the oxygen barrier film 118.

Subsequently, as illustrated in FIG. 11M, the noble metal film (conductive film) 44a is formed on the entire surface by a sputtering method or the like. The conductive film 44a forms a part of the lower electrode 48a of the capacitor 62a. As the conductive film 44a, for example, an iridium film is formed. The thickness of the conductive film 44a is set, for example, to approximately 100 nm. The conductive film 44a is formed, for example, under the following conditions. The substrate temperature is set, for example, to 450° C. As a gas introduced into a film formation chamber, for example, an Ar gas is used. The pressure inside the film formation chamber is set, for example, to 0.11 Pa. A sputtering power is set, for example, to 0.3 kW.

Next, a heat treatment is performed in an argon atmosphere by an RTA method or the like. The temperature for the heat treatment is set, for example, to 650° C. The time for the heat treatment is set, for example, to 60 seconds. This heat treatment is performed to grow crystal grains in the noble metal film 44a and also to uniform the size of the crystal grains therein.

Next, the amorphous noble metal oxide film 45a is formed on the entire surface by a sputtering method or the like. A noble metal contained in the noble metal oxide film 45a is preferably the same element as that of a noble metal contained in the conductive film 44a. The noble metal oxide film 45a is turned into the noble metal film 46a by reduction in a subsequent step. The noble metal film 46a formed by reducing the noble metal oxide film 45a forms a part of the lower electrode 48a of the capacitor 62a. As the amorphous noble metal oxide film 45a, for example, an iridium oxide film (IrO_{X} film) is formed.

The thickness of the noble metal oxide film 45a is set to approximately 25 nm.

That is, when the ferroelectric film 50a is formed by an MOCVD method in a subsequent step, the noble metal oxide film 45a is exposed to a relatively strong reducing atmosphere. Hence, when the thickness of the noble metal oxide film 45a is set relatively small, the noble metal oxide film 45a is reduced before the formation of the ferroelectric film 50a is completed. In this case, an excellent ferroelectric film 50a having uniform crystallinity may not be obtained in some cases. When the thickness of the noble metal oxide film 45a is set to 25 nm or more, the ferroelectric film 50a is formed in the state in which the noble metal oxide film 45a remains on the noble metal film 44a to a certain extent. Hence, when the thickness of the noble metal oxide film 45a is set to 25 nm or more, the excellent ferroelectric film 50a having uniform crystallinity may be formed. By the exemplary reason described above, in this embodiment, the thickness of the noble metal oxide film 45a is set to approximately 25 nm.

The temperature for the film formation of the noble metal oxide film 45a is set, for example, to 60°. As a gas introduced into a film formation chamber when the noble metal oxide film 45a is formed, for example, a mixed gas containing an Ar gas and an O₂ gas is used. The flow rate of an Ar gas is set, for example, to 186 sccm. The flow rate of an O₂ gas is set, for example, to 14 sccm.

Subsequently, as illustrated in FIG. 11N, the ferroelectric film (first ferroelectric film) 50a is formed on the entire surface by an MOCVD method or the like. As the ferroelectric film 50a, for example, a PLZT film, which is a PZT film added with La, is formed. The thickness of the ferroelectric film 50a is set, for example, to approximately 30 to 150 nm. More preferably, the thickness of the ferroelectric film 50a is set, for example, to approximately 50 to 120 nm. In this embodiment, the thickness of the ferroelectric film 50a is set, for example, to 90 nm.

The amount of La in the ferroelectric film 50a is set to 0.1 to 4.0 mole percent. In this embodiment, the amount of La in the ferroelectric film 50a is set, for example, to 2.0 mole percent.

When the PLZT ferroelectric film 50a is formed by an MOCVD method, raw material gases are generated by vaporizing liquid raw materials for Pb, Zr, Ti, and La, and a PLZT film is formed using these raw material gases.

The liquid raw materials for Pb, Zr, Ti, and La are formed as described below. The liquid raw material for Pb is formed, for example, by dissolving Pb(DPM)₂ in a solvent. As the solvent, for example, tetrahydrofuran (THF) is used. The concentration of Pb(DPM)₂ in the liquid raw material for Pb is set, for example, to approximately 0.3 mole/L. The liquid raw material for Zr is formed, for example, by dissolving Zr(dmhd)₄ in a solvent. As the solvent, for example, THF is used. The concentration of Zr(dmhd)₄ in the liquid raw material for Zr is set, for example, to approximately 0.3 mole/L. The liquid raw material for Ti is formed, for example, by dissolving [Ti(O-iOr)₂(DPM)₂] in a solvent. As the solvent, for example, THF is used. The concentration of [Ti(O-iOr)₂(DPM)₂] in the liquid raw material for Ti is set, for example, to approximately 0.3 mole/L. The liquid raw material for La is formed, for example, by dissolving La(DPM)₃ in a solvent. As the solvent, for example, THF is used. The concentration of La(DPM)₃ in the liquid raw material for La is set, for example, to approximately 0.3 mole/L.

A raw material gas for PLZT is generated in such a way that the liquid raw material for Pb, the liquid raw material for Zr, the liquid raw material for Ti, and the liquid raw material for La are charged in respective vaporizers together with a solvent, and the liquid raw materials thus charged are vaporized by the vaporizers. As a solvent, for example, THF is used. The supply rate of the solvent is set, for example, to 0.474 ml/minute. The supply rate of the liquid raw material for Pb is set, for example, to 0.326 ml/minute. The supply rate of the liquid raw material for Zr is set, for example, to 0.200 ml/minute. The supply rate of the liquid raw material for Ti is set, for example, to 0.200 ml/minute. The supply rate of the liquid raw material for La is set, for example, to 0.020 ml/minute.

The ferroelectric film 50a is formed by an MOCVD method under the following conditions. That is, the pressure inside a film formation chamber is set, for example, to 665 Pa (5 Torr). The substrate temperature is set, for example, to 620° C. The time for the film formation is set, for example, to 620 seconds.

When the film formation is performed under the conditions described above, the PLZT ferroelectric film 50a is formed to have a thickness of approximately 90 nm.

When the ferroelectric film 50a is formed by an MOCVD method, the ferroelectric film 50a is formed in a crystallized state. Since the ferroelectric film 50a is formed on the amorphous noble metal oxide film 45a, even if the crystallinity of the noble metal film 44a is not sufficiently uniform, the ferroelectric film 50a may be formed to have uniform crystallinity. In addition, when the ferroelectric film 50a is formed by an MOCVD method, since the amorphous noble metal oxide film 45a is exposed to a relatively strong reducing atmosphere, the amorphous noble metal oxide film 45a is reduced, so that the noble metal film 46a is formed. In addition, when the ferroelectric film 50a is formed by an MOCVD method, oxygen is released from the noble metal oxide film 45a. The oxygen released from the noble metal oxide film 45a compensates for oxygen vacancies in the ferroelectric film 50a. Hence, a ferroelectric film 50a having excellent crystallinity is obtained. When an iridium oxide film is formed as the noble metal oxide film 45a, the noble metal film (conductive film) 46a which is an iridium film is formed.

In this embodiment, although the case in which the ferroelectric film 50a is formed by an MOCVD method is described by way of example, the formation method of the ferroelectric film 50a is not limited to an MOCVD method. For example, the ferroelectric film 50a may be formed by a sputtering method.

When the ferroelectric film 50a is formed by a sputtering method, as in the method for manufacturing a semiconductor device according to the first embodiment which is described with reference to FIGS. 2F to 2H, the lower electrode and the ferroelectric film may be formed by a sputtering method.

Subsequently, as illustrated in FIG. 11O, the ferroelectric film (second ferroelectric film) 52 is formed on the entire surface by a sputtering method or the like. In more particular, by a high frequency sputtering method, the ferroelectric film 52 is formed. The ferroelectric film 52 forms a part of the capacitor dielectric film 54a of the capacitor 62a. As a material for the ferroelectric film 52, lead zirconate titanate added with La, Ca, and Sr, that is, PZT added with La, Ca, and Sr, is used. A PZT film added with La, Ca, and Sr is called a CSPLZT film. The thickness of the ferroelectric film 52 is set, for example, to approximately 5 to 20 nm. In this embodiment, the thickness of the ferroelectric film 52 is set, for example, to approximately 15 nm.

The amount of La added to the ferroelectric film 52 is set to 0.1 to 4.0 mole percent. In this embodiment, the amount of La added to the ferroelectric film 52 is set, for example, to 2.0 mole percent.

The amount of Sr added to the ferroelectric film 52 is set to 0.1 to 3.0 mole percent. In this embodiment, the amount of Sr added to the ferroelectric film 52 is set, for example, to 2.0 mole percent.

The amount of Ca added to the ferroelectric film 52 is set to 0.1 to 6.0 mole percent. In this embodiment, the amount of Ca added to the ferroelectric film 52 is set, for example, to 5.0 mole percent.

The total amount of the impurities (La, Sr, and Ca) added to the ferroelectric film 52 is set to 10.0 mole percent or less.

Accordingly, the capacitor dielectric film 54a is formed from the ferroelectric film 50a and the ferroelectric film 52.

Subsequently, as illustrated in FIG. 11P, the conductive film 56 is formed in a crystallized state on the entire surface by a sputtering method or the like. The conductive film 56 forms a part of the upper electrode 60a of the capacitor 62a. As the conductive film 56, an iridium oxide film (IrO_{X} film) is formed. The conductive film 56 is preferably formed to have a relatively small thickness so that oxygen is sufficiently supplied to the ferroelectric film 52 through the conductive film 56 by a heat treatment in a subsequent step. The thickness of the conductive film 56 is set, for example, to approximately 25 nm.

The conductive film 56 is formed, for example, under the following conditions. The substrate temperature is set, for example, to approximately 300° C. As a gas introduced into a film formation chamber, for example, an Ar gas and an O₂ gas are used. The flow rate of an Ar gas is set, for example, to approximately 140 sccm. The flow rate of an O₂ gas is set, for example, to approximately 60 sccm. A sputtering power is set, for example, to approximately 1 kW.

Next, a heat treatment is performed in an atmosphere containing oxygen by an RTA method or the like. Accordingly, the crystallinity of each of the ferroelectric films 50a and 52 is improved. In addition, oxygen is supplied to the capacitor dielectric film 54a through the conductive film 56, and hence oxygen vacancies in the capacitor dielectric film 54a are compensated for. In addition, this heat treatment is performed to recover plasma damage generated in the conductive film 56. In addition, this heat treatment is to improve the adhesion between the conductive film 56 and the ferroelectric film 52. By this heat treatment, for example, peeling of the upper electrode 60a is substantially suppressed, and as a result, an improvement in yield may be realized.

The heat treatment is performed, for example, under the following conditions. The substrate temperature is set, for example, to approximately 720° C. The time for the heat treatment is set, for example, to 60 seconds. As an atmosphere in a chamber, for example, a mixed gas atmosphere containing an Ar gas and an O₂ gas is used. The flow rate of an Ar gas is set, for example, to 2,000 sccm. The flow rate of an O₂ gas is set, for example, to 20 sccm.

Next, the conductive film 58 is formed on the entire surface by a sputtering method or the like. The conductive film 58 forms a part of the upper electrode 60a of the capacitor 62a. As the conductive film 58, for example, an iridium oxide (IrO_{Y}) film (0<Y≦2) is formed. The oxygen composition ratio Y of the iridium oxide film (IrO_{Y} film) formed as the conductive film 58 is preferably higher than the oxygen composition ratio X of the iridium oxide film (IrO_{X} film) formed as the conductive film 56. The thickness of the conductive film 58 is set, for example, to approximately 100 to 300 nm. In this embodiment, the thickness of the conductive film 58 is set to approximately 200 nm.

The conductive film 58 is a film to form an upper electrode 60a having a sufficient thickness in cooperation with the conductive film 56. Accordingly, since the upper electrode 60a having a sufficient thickness is formed, the capacitor dielectric film 54a may be substantially prevented from being seriously damaged when etching or the like is performed.

The composition of an iridium oxide film used as the conductive film 58 preferably has a stoichiometric composition of IrO₂. An exemplary reason for this is that since an iridium oxide film having a stoichiometric composition has no catalytic action on hydrogen, the capacitor dielectric film 54a may be substantially prevented from being reduced by hydrogen.

Next, the hydrogen barrier film 120 is formed by a sputtering method or the like. The hydrogen barrier film 120 forms a part of the upper electrode 60a. The thickness of the hydrogen barrier film 120 is set, for example, to approximately 50 mm. As the hydrogen barrier film 120, for example, an iridium film is formed. The hydrogen barrier film 120 functions to substantially prevent the capacitor dielectric film 54a from being reduced by hydrogen. The hydrogen barrier film 120 is formed, for example, under the following conditions. As a gas introduced into a film formation chamber, for example, an Ar gas is used. The pressure inside the film formation chamber is set, for example, to approximately 1 Pa. A sputtering power is set, for example, to approximately 1.0 W.

In this embodiment, although the case in which an iridium film is used as the hydrogen barrier film 120 is described by way of example, the hydrogen barrier film 120 is not limited to an iridium film. For example, a Pt film or an SrRuO₃ film may also be used as the hydrogen barrier film 120.

Next, the bottom surface (rear surface) of the semiconductor substrate 10 is cleaned (backside cleaning).

Next, as illustrated in FIG. 11Q, a protective film 138 is formed on the entire surface by a sputtering method. The protective film 138 functions as a part of a hard mask. As the protective film 138, for example, a TiN film is formed.

In this embodiment, although the case in which a TiN film is formed as the protective film 138 is described by way of example, the protective film 138 is not limited to a TiN film. For example, a TiAlN film, a TaAlN film, or a TaN film may also be used as the protective film 138. In addition, the protective film 138 may also be a laminate film containing the films mentioned above.

Next, a protective film 140 is formed on the entire surface by a plasma TEOS CVD method or the like. The protective film 140 functions as the hard mask in cooperation with the protective film 138.

Next, a photoresist film (not illustrated) is formed on the entire surface by a spin coating method or the like.

Next, by a photolithographic technique, the photoresist film is patterned to have a plane shape of the capacitor 62a.

Next, the protective film 140 is etched using the photoresist film as a mask.

Next, using the protective film 140 thus etched as a mask, the protective film 138 is etched.

Accordingly, the hard mask (not illustrated) is formed from the protective films 138 and 140 thus etched.

Next, the hydrogen barrier film 120, the conductive film 58, the conductive oxide film 56, the ferroelectric film 52, the ferroelectric film 50a, the conductive film 46a, and the conductive film 44a are etched using the hard mask as a mask by a plasma etching or the like. As an etching gas, for example, a mixed gas containing an HBr gas, an O₂ gas, an Ar gas, and a C₄O₈ gas is used.

Accordingly, the lower electrode 48a is formed from the conductive films 44a and 46a. In addition, the capacitor dielectric film 54a is formed from the ferroelectric films 50a and 52. In addition, the upper electrode 60a is formed from the conductive films 56 and 58 and the hydrogen barrier film 120. The lower electrode 48a, the capacitor dielectric film 54a, and the upper electrode 60a collectively form the capacitor 62a.

Next, the protective film 140 is removed, for example, by dry etching or wet etching (see FIG. 11R).

Next, the oxygen barrier film 118, the adhesive film 116, and the underlayer 114 are etched, for example, by dry etching. In this step, the protective film 138 is also removed by etching (see FIG. 11S). When the etching is performed, for example, a downflow type plasma etching apparatus is used. As a gas introduced into a chamber, for example, a mixed gas containing a CF₄ gas and an O₂ gas is used. The flow rate ratio of a CF₄ gas is set, for example, to approximately 5%. The flow rate ratio of an O₂ gas is set, for example, to approximately 95%. A high frequency electrical power applied to an upper electrode inside the chamber is set, for example, to 1,400 W at 2.45 GHz. The substrate temperature is set, for example, to 200° C.

Next, as illustrated in FIG. 11T, the protective film 122 is formed on the entire surface by a sputtering method or the like. The protective film 122 functions to substantially prevent the capacitor dielectric film 54a from being reduced by hydrogen, moisture, and the like. As the protective film 122, for example, an aluminum oxide film is formed. The thickness of the protective film 122 is set, for example, to approximately 20 nm.

In this embodiment, although the case in which the protective film 122 is formed by a sputtering method is described by way of example, the method for forming the protective film 122 is not limited to a sputtering method. For example, the protective film 122 may be formed by an MOCVD method. In this embodiment, the thickness of the protective film 122 is set, for example, to approximately 2 to 5 nm.

Next, a heat treatment is performed in an oxygen atmosphere. This heat treatment is performed to supply oxygen to the capacitor dielectric film 54a and to improve the electrical properties of the capacitor 62a. The temperature for the heat treatment is set, for example, to 500° C. to 700° C. When the capacitor dielectric film 54a is a PZT film, the substrate temperature is set, for example, to 600° C., and the time for the heat treatment is set, for example, to 60 minutes.

Next, the protective film 124 is formed on the entire surface by a CVD method or the like. The protective film 124 functions to substantially prevent the capacitor dielectric film 54a from being reduced by hydrogen, moisture, and the like. The thickness of the protective film 124 is set, for example, to approximately 38 nm. As the protective film 124, for example, an aluminum oxide film is formed.

In addition, in order to substantially prevent peeling of the protective film 124, a heat treatment may be performed before the protective film 124 is formed. The heat treatment is performed, for example, under the following conditions. The substrate temperature is set, for example, to approximately 350° C. The time for the heat treatment is set, for example, to approximately 1 hour.

In this embodiment, although the case in which an aluminum oxide film is formed as the protective film 124 is described by way of example, the protective film 124 is not limited to an aluminum oxide film. As the protective film 124, for example, a titanium oxide film, a tantalum oxide film, a zirconium oxide film, an aluminum nitride film, a tantalum nitride film, or an aluminum oxynitride film may also be formed.

Next, as illustrated in FIG. 11U, the interlayer insulating film 68 is formed, for example, by a plasma TEOS CVD method. As the interlayer insulating film 68, for example, a silicon oxide film is formed. The thickness of the interlayer insulating film 68 is set, for example, to approximately 1.5 μm. As a raw material gas, for example, a mixed gas containing a TEOS gas, an oxygen gas, and a helium gas is used.

In this embodiment, although the case in which a silicon oxide film is formed as the interlayer insulating film 68 is described by way of example, the interlayer insulating film 68 is not limited to a silicon oxide film. For example, an inorganic film having insulating properties may be appropriately used.

Next, the surface of the interlayer insulating film 68 is planarized, for example, by a CMP method.

Next, a heat treatment is performed, for example, in a plasma atmosphere generated using an N₂O gas or an N₂ gas. This heat treatment functions to remove moisture in the interlayer insulating film 68 and also functions to change the film quality thereof so that moisture is not likely to enter the interlayer insulating film 68. The temperature for the heat treatment is set, for example, to 350° C. The time for the heat treatment is set, for example, to 2 minutes. In this heat treatment, the surface of the interlayer insulating film 68 is nitrided, and as a result, a silicon oxynitride film (not illustrated) is formed on the surface of the interlayer insulating film 68.

Next, as illustrated in FIG. 11U, the protective film 70 is formed, for example, by a sputtering method or a CVD method. As the protective film 70, for example, an aluminum oxide film is formed. The thickness of the protective film 70 is set, for example, to approximately 20 to 100 nm. The protective film 70 functions to substantially prevent the capacitor dielectric film 54a from being reduced by hydrogen, moisture, and the like. Since being formed on the interlayer insulating film 68 having a flat surface, the protective film 70 is formed flat.

Next, for example, by a plasma TEOS CVD method, the interlayer insulating film 72 is formed. As the interlayer insulating film 72, for example, a silicon oxide film is formed. The thickness of the interlayer insulating film 72 is set, for example, to approximately 800 nm to 1 μm.

In this embodiment, although the case in which a silicon oxide film is formed as the interlayer insulating film 72 is described by way of example, the interlayer insulating film 72 is not limited to a silicon oxide film. For example, a silicon oxynitride film or a silicon nitride film may also be used as the interlayer insulating film 72.

Next, for example, by a CMP method, the surface of the interlayer insulating film 72 is planarized.

Next, by a photolithographic technique, the interlayer insulating film 72, the protective film 70, the interlayer insulating film 68, the protective film 124, the protective film 122, and the interlayer insulating film 104 are etched, so that the contact hole 126a reaching the conductive plug 36 is formed. In addition, by a photolithographic technique, the interlayer insulating film 72, the protective film 70, the interlayer insulating film 68, the protective film 124, and the protective film 122 are etched, so that the contact hole 126b reaching the upper electrode 60a is formed.

Next, a heat treatment is performed in an oxygen atmosphere. This heat treatment is performed to supply oxygen to the capacitor dielectric film 54a, to compensate for oxygen vacancies in the capacitor dielectric film 54a, and to recover the electrical properties of the capacitor 62a. The substrate temperature used when the heat treatment is performed is set, for example, to 450° C.

Next, a heat treatment is performed in an inert gas atmosphere or in vacuum. This heat treatment is performed to release gases from the interlayer insulating films 72, 68, and 104 (degassing).

Next, by high frequency etching, a surface treatment is performed on inner wall surfaces of the contact holes 126a and 126b.

Next, the adhesive film 128 is formed on the entire surface by a sputtering method or the like. As the adhesive film 128, for example, a TiN film is formed. The thickness of the adhesive film 128 is set, for example, to approximately 125 nm. When a TiN film is formed as the adhesive film 128, Ti is used as a material for a target. As an atmosphere in a film formation chamber, a mixed gas atmosphere containing an Ar gas and a N₂ gas is used. The flow rate of an Ar gas is set, for example, to 50 sccm. The flow rate of a N₂ gas is set, for example, to 90 sccm. The temperature for the film formation is set, for example, to 200° C.

Next, a conductive film is formed on the entire surface by a CVD method or the like. As the conductive film, for example, a tungsten film is formed. The thickness of the conductive film is set, for example, to approximately 300 nm.

Next, the conductive film and the adhesive film 128 are polished, for example, by a CMP method until the surface of the interlayer insulating film 72 is exposed. Accordingly, the conductive plugs 130a and 130b are formed from the conductive film (see FIG. 11V).

Next, plasma cleaning is performed. As a gas used for the plasma cleaning, for example, an Ar gas is used. Accordingly, native oxide films and the like present on the surfaces of the conductive plugs 130a and 130b are removed.

Next, for example, the TiN film 82, the AlCu alloy film 84, the Ti film 86, and the TiN film 88 are sequentially laminated by a sputtering method or the like, so that a laminate film is formed. The thickness of the TiN film 82 is set, for example, to 50 nm. The thickness of the AlCu alloy film 84 is set, for example, to 550 nm. The thickness of the Ti film 86 is set, for example, to 5 nm. The thickness of the TiN film 88 is set, for example, to 50 nm.

Next, the laminate film is etched by a photolithographic technique. Accordingly, the wires 90 are formed (see FIG. 11W).

Next, furthermore, a plurality of layers each containing an interlayer insulating film (not illustrated), at least one conductive plug (not illustrated), and at least one wire (not illustrated) is formed.

Accordingly, the semiconductor device of this embodiment is manufactured.

As in this embodiment, a stacked memory cell may also be formed.

Besides the above embodiments, various modifications may be performed without departing from the scope of the present invention.

For example, in the above embodiments, although the case in which a PZT film added with La is formed as the ferroelectric films 50 and 50a is described by way of example, the ferroelectric films 50 and 50a are not limited to a PZT film added with La. For example, another ferroelectric material having a perovskite structure and added with La may also be used as a material for the ferroelectric films 50 and 50a. In addition, as the ferroelectric films 50 and 50a, a ferroelectric film having a bismuth layer structure and added with La may also be used. As the ferroelectric films 50 and 50a having a bismuth layer structure and added with La, for example, a (Bi₁₋ₓRₓ)Ti₃O₁₂ film (R indicates a rare earth element, 0<X<1) added with La, an SrBi₂Ta₂O₉ film (SBT film) added with La, or an SrBi₄Ti₄O₁₅ film added with La may be used. In addition, as the ferroelectric films 50 and 50a having a bismuth layer structure and added with La, for example, a BiFeO₃ film added with La or a BiTiO₃ film added with La may also be used. In addition, the crystallization temperature of an SrBi₄Ti₄O₁₅ film added with La or that of a BiTiO₃ film added with La is higher than the crystallization temperature of a PLZT film. Hence, when an SrBi₄Ti₄O₁₅ film added with La, a BiTiO₃ film added with La, or the like is used as the ferroelectric films 50 and 50a, the temperature for heat treatment is preferably set, for example, to approximately 600° C. to 650° C.

In addition, in the above embodiments, although the case in which a PZT film added with La, Sr, and Ca is formed as the ferroelectric film 52 is described by way of example, the ferroelectric film 52 is not limited to a PZT film added with La, Sr, and Ca. For example, another ferroelectric material having a perovskite structure and added with La, Sr, and Ca may also be used as a material for the ferroelectric film 52. In addition, for example, a ferroelectric film having a bismuth layer structure may also be used. As the ferroelectric film 52 described above, for example, a (Bi₁₋ₓRₓ)Ti₃O₁₂ film (R indicates a rare earth element, 0<X<1) added with La, Sr, and Ca or an SrBi₂Ta₂O₉ film (SBT film) added with La, Sr, and Ca may be used. In addition, as the ferroelectric film 52, for example, an SrBi₄Ti₄O₁₅ film added with La, Sr, and Ca, a BiFeO₃ film added with La, Sr, and Ca, or a BiTiO₃ film added with La, Sr, and Ca may also be used.

In addition, in the above embodiments, although the case in which a TiN film is used as the adhesive films 78 and 128 is described by way of example, the adhesive films 78 and 128 are not limited to a TiN film. For example, as the adhesive films 78 and 128, a TaN film, a CrN film, an HfN film, a ZrN film, a TiAlN film, a TaAlN film, a TiSiN film, a TaSiN film, a CrAlN film, an HfAlN film, a ZrAlN film, a TiON film, a TaON film, a CrON film, or an HfON film may also be used. In addition, as the adhesive films 78 and 128, for example, a ZrON film, a TiAlON film, a TaAlON film, a CrAlON film, an HfAlON film, a ZrAlON film, a TiSiON film, a TaSiON film, an Ir film, an Ru film, an IrO_{X} film, or an RuO_{X} film may also be used. In addition, a laminate film formed by sequentially laminating a Ti film and a TiN film may also be used as the adhesive films 78 and 128. In addition, a laminate film formed by sequentially laminating a Ti film and a TaN film may also be used as the adhesive films 78 and 128. In addition, a laminate film formed by sequentially laminating a Ta film and a TiN film may also be used as the adhesive films 78 and 128. Furthermore, a laminate film formed by sequentially laminating a Ta film and a TaN film may also be used as the adhesive films 78 and 128.

In addition, in the above embodiments, although the case in which an iridium oxide film is used as the conductive film 56 is described by way of example, the conductive film 56 is not limited to an iridium oxide film. For example, a conductive oxide film of an oxide of Ru, Rh, Re, Os, or Pd may also be used as a material for the conductive film 56. In addition, a conductive oxide film of SrRuO₃ or the like may also be used as the material for the conductive film 56. In addition, a laminate film containing the films mentioned above may also be used as the conductive film 56. In addition, a laminate film containing the conductive oxide film mentioned above and a noble metal film may also be used as the conductive film 56.

In addition, in the above embodiments, although the case in which an iridium oxide film is used as the conductive film 58 is described by way of example, the conductive film 58 is not limited to an iridium oxide film. For example, a conductive oxide film of an oxide of Ru, Rh, Re, Os, or Pd may also be used as a material for the conductive film 58. In addition, a conductive oxide film of SrRuO₃ or the like may also be used as the material for the conductive film 58. In addition, a laminate film containing the films mentioned above may also be used as the conductive film 58. In addition, a laminate film containing the conductive oxide film mentioned above and a noble metal film may also be used as the conductive film 58.

In addition, in the above embodiment, although the case in which tungsten is used as a material for the conductive plugs 80a to 80c is described by way of example, the material for the conductive plugs 80a to 80c is not limited to tungsten. For example, as the material for the conductive plugs 80a to 80c, copper (Cu) or the like may also be used. In addition, the conductive plugs 80a to 80c may be formed from a laminate film containing a tungsten film and a copper film. In addition, the conductive plugs 80a to 80c may be formed from a laminate film containing a tungsten film and a polysilicon film.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method for manufacturing a semiconductor device comprising:
forming a lower electrode film, which includes platinum, above a semiconductor substrate;
forming a first ferroelectric film, which includes lead zirconate titanate with La, on the lower electrode film;
forming a second ferroelectric film, which includes lead zirconate titanate with La, Ca, and Sr, directly on the first ferroelectric film, the second ferroelectric film having a thickness smaller than that of the first ferroelectric film and includes amounts of Ca and Sr greater than amounts of Ca and Sr that may be present in the first ferroelectric film;
forming an upper electrode film which includes a conductive oxide, on the second ferroelectric film; and
patterning the upper electrode film, the second ferroelectric film, the first ferroelectric film, and the lower electrode film to form a capacitor which includes a lower electrode, a capacitor dielectric film, and an upper electrode.

2. The method for manufacturing a semiconductor device according to claim 1,
wherein, in forming the upper electrode film, a crystallized first conductive oxide film is formed on the second ferroelectric film.

3. The method for manufacturing a semiconductor device according to claim 2,
wherein, in forming the upper electrode film, a second conductive oxide film, which has a higher oxygen composition ratio than that of the first conductive oxide film, is formed on the first conductive oxide film.

4. The method for manufacturing a semiconductor device according to claim 3,
wherein the first conductive oxide film is an iridium oxide film, and
the second conductive oxide film is an iridium oxide film different from the iridium oxide film of the first conductive oxide film.

5. The method for manufacturing a semiconductor device according to claim 1,
wherein the first ferroelectric film is formed by a sputtering method.

6. The method for manufacturing a semiconductor device according to claim 1,
wherein the second ferroelectric film is formed by a sputtering method.

7. The method for manufacturing a semiconductor device according to claim 1,
wherein an amount of La in the first ferroelectric film is about 0.1 to about 4.0 mol percent.

8. The method for manufacturing a semiconductor device according to claim 1,
wherein an amount of La in the second ferroelectric film is about 0.1 to about 4.0 mole percent,
an amount of Ca in the second ferroelectric film is about 0.1 to about 6.0 mole percent, and
an amount of Sr in the second ferroelectric film is about 0.1 to about 3.0 mole percent.

9. The method for manufacturing a semiconductor device according to claim 1,
wherein the first ferroelectric film has a thickness of about 30 to about 150 nm, and
the second ferroelectric film has a thickness of about 5 to about 20 nm.
